(19) United States
(12) Patent Application Publication
(10) Pub. No.: US 2015/0311441 A1
(43) Pub. Date: Oct. 29, 2015

(54) METAL COMPLEX COMPOUND, AND ORGANIC LIGHT-EMITTING ELEMENT AND DISPLAY DEVICE CONTAINING THE SAME

(71) Applicant: CANON KABUSHIKI KAISHA, Tokyo (JP)

(72) Inventors: Jun Kamatani, Tokyo (JP); Naoki Yamada, Inagi-shi (JP); Tetsuya Kosuge, Yokohama-shi (JP); Hirokazu Miyashita, Tokyo (JP)

(21) Appl. No.: 14/691,458

(22) Filed: Apr. 20, 2015

(30) Foreign Application Priority Data
Apr. 23, 2014 (JP) 2014-089535
Apr. 28, 2014 (JP) 2014-093085

(51) Int. Cl. H01L 29/08; C07F 5/02

(52) U.S. Cl. CPC H01L 51/008; C07F 5/05; H01L 27/3248; H01L 29/7869; H01L 51/529

(57) ABSTRACT

A metal complex compound is expressed by the following general formula [1]:

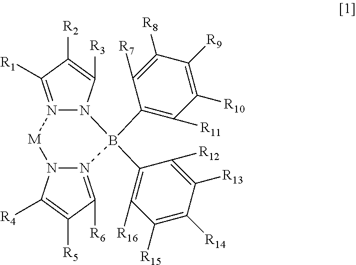

In general formula [1], M represents sodium or potassium. R₁ to R₁₆ each represent a hydrogen atom or a substituent.

### BACKGROUND OF THE INVENTION

1. Field of the Invention

The present application relates to a metal complex compound, and to an organic light-emitting element, a display device, an image information processing unit, a lighting device, an image forming apparatus and an exposure unit, each containing the metal complex compound.

2. Description of the Related Art

An organic light-emitting element includes an anode and a cathode, and an organic compound layer between the anode and the cathode. The light-emitting element emits light by recombination of holes injected from the anode and electrons injected from the cathode in a luminescent layer that is the organic compound layer. Recent significant advances in development of organic light-emitting elements have been achieving thin, lightweight light-emitting devices that can emit a variety of emission wavelengths and respond rapidly at a low driving voltage.

In order to reduce the driving voltage of an organic light-emitting element, it is effective to increase an ability to inject electrons. This ability is hereinafter referred to as electron injection property. From the viewpoint of increasing the electron injection property, the layer in contact with the cathode is made of an inorganic material such as lithium fluoride. Lithium fluoride is however hygroscopic and is not suitable to be used in organic light-emitting elements. International Publication No. WO 2013/079676 discloses a metal salt other than lithium fluoride as expressed by the following general formula 1-A. This patent document describes three processes for synthesizing a metal complex having three or more pyrazole groups as ligands. This patent document also discloses that the metal complex is used in an electron transport layer not in contact with the cathode in a light-emitting element.

W. J. Layton, “Syntheses and reactions of pyrazaboles” Inorganic Chemistry, 1985, 24(10), 1454-1457 teaches a process for synthesizing a compound using potassium, and Swiatoslaw. Trofimenko, Boron-pyrazole chemistry. IV. Carbon- and boron-substituted poly[(1-pyrazolyl)borates]”, Journal of the American Chemical Society” 1967, 89, (24), 6288-6294 teaches a process for synthesizing a compound using sodium. These documents however do not describe application of these compounds to organic light-emitting elements.

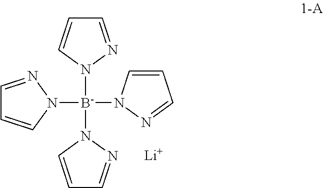 [SMILES: c1cnn([B-](n2cccn2)(n2cccn2)n2cccn2)c1 ; [Li+]]

Metal salts used as a material of electron injection layers, such as lithium fluoride, exhibit a high electron injection property, but are soluble in water. Organic light-emitting elements containing a metal salt such as lithium fluoride are unstable and accordingly have short lives.

### SUMMARY OF THE INVENTION

The present application provides a metal complex compound having a high electron injection property and a low solubility in water.

According to an aspect of the application, a metal complex compound expressed by the following general formula [1] is provided.

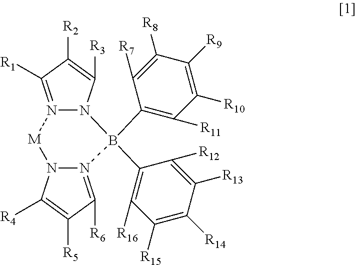

In general formula [1], M represents sodium or potassium. R₁ to R₁₆ each represent a hydrogen atom or a substituent. The substituent is a species selected from the group consisting of halogen atoms, the cyano group, alkyl groups that may be substituted with a halogen atom, alkoxy groups that may be substituted with a halogen atom, and aromatic hydrocarbon groups.

The aromatic hydrocarbon groups may be substituted with at least one species selected from the group consisting of halogen atoms, substituted or unsubstituted alkyl groups, substituted or unsubstituted alkoxy groups, substituted amino groups, and substituted or unsubstituted aromatic hydrocarbon groups.

At least one of the R₁ to R₁₆ is the substituent.

Further features of the present invention will become apparent from the following description of exemplary embodiments with reference to the attached drawings.

### BRIEF DESCRIPTION OF THE DRAWINGS

FIG. 1 is a schematic sectional view of a structure including organic light-emitting elements according to an embodiment and switching elements connected to the organic light-emitting elements.

FIG. 2 is a schematic view of an image forming apparatus including the organic light-emitting elements according to an embodiment.

FIGS. 3A and 3B are schematic views of exposure units including the organic light-emitting elements according to an embodiment.

FIG. 4 is a schematic view of a lighting device including the organic light-emitting elements according to an embodiment.

### DESCRIPTION OF THE EMBODIMENTS

The present application provides a metal complex compound containing a boron atom. The ligand of the metal complex compound contains boron, pyrazole rings and phenyl groups. All the unshared electron pairs in the pyrazole rings are used for the coordinate bonds to the boron and to sodium or potassium. The phenyl groups bind with the boron to contribute to enhancing the hydrophobicity of the compound.

The metal complex compound is expressed by the following general formula [1]:

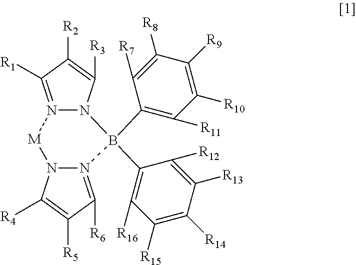

In general formula [1], M represents sodium or potassium. R₁ to R₁₆ each represent a hydrogen atom or a substituent. The substituent is a species selected from the group consisting of halogen atoms, the cyano group, alkyl groups that may be substituted with a halogen atom, alkoxy groups that may be substituted with a halogen atom, and aromatic hydrocarbon groups.

At least one of the R₁ to R₁₆ is the substituent. Hence, at least one of the R₁ to R₁₆ is not hydrogen.

Since at least one of the R₁ to R₁₆ is a substituent, the metal complex compound is less soluble in water than compounds in which all the R₁ to R₁₆ are hydrogen.

The halogen atoms that can be any of the R₁ to R₁₆ include fluorine, chlorine, bromine, and iodine.

The alkyl groups that can be any of the R₁ to R₁₆ desirably have a carbon number in the range of 1 to 6. Examples of such an alkyl group include methyl, ethyl, n-propyl, isopropyl, n-butyl, isobutyl, sec-butyl, tert-butyl, n-pentyl, isopentyl, tert-pentyl, neopentyl, n-hexyl, and cyclohexyl. Among these alkyl groups, methyl and tert-butyl are advantageous.

The alkyl group may be substituted with a halogen atom, and the halogen atom may be fluorine.

The alkoxy groups that can be any of the R₁ to R₁₆ include, but are not limited to, methoxy, ethoxy, isopropoxy, n-butoxy, and tert-butoxy. Among these alkoxy groups, methoxy and ethoxy are advantageous.

The alkoxy group may be substituted with a halogen atom, and the halogen atom may be fluorine.

The aromatic hydrocarbon groups that can be any of the R₁ to R₁₆ include, but are not limited to, phenyl, naphthyl, phenanthryl, anthryl, fluorenyl, biphenylenyl, acenaphthylenyl, chrysenyl, pyrenyl, triphenylenyl, picenyl, fluoranthenyl, perylenyl, naphthacenyl, biphenyl, and terphenyl. Among these aromatic hydrocarbon groups, phenyl, naphthyl, fluorenyl and biphenyl are advantageous, and phenyl is more advantageous.

The aromatic hydrocarbon group that can be any of the R₁ to R₁₆ may be further substituted. In this instance, the substituent of the aromatic hydrocarbon group is not particularly limited, and may be selected from the group consisting of halogen atoms, substituted or unsubstituted alkyl groups, substituted or unsubstituted alkoxy groups, substituted amino groups, and substituted or unsubstituted aromatic hydrocarbon groups.

If the substituent of the aromatic hydrocarbon group is an alkyl group, examples of the alkyl group include those cited as the alkyl groups that can be the R₁ to R₁₆. Advantageously, the alkyl group has a carbon number in the range of 1 to 6, and methyl and tert-butyl are more advantageous. This alkyl group may be substituted and advantageously with a group containing a halogen atom, such as a trifluoromethyl group.

If the substituent of the aromatic hydrocarbon group is a halogen atom, examples of the halogen atoms include those cited as the halogen atoms that can be the R₁ to R₁₆.

If the substituent of the aromatic hydrocarbon group is an alkoxy group, examples of the alkoxy groups include those cited as the alkoxy groups that can be the R₁ to R₁₆.

If the substituent of the aromatic hydrocarbon group is a substituted amino group, examples of the substituted amino group include, but are not limited to, N-methylamino, N-ethylamino, N,N-dimethylamino, N,N-diethylamino, N-methyl-N-ethylamino, N-benzylamino, N-methyl-N-benzylamino, N,N-dibenzylamino, anilino, N,N-diphenylamino, N,N-dinaphthylamino, N,N-difluorenylamino, N-phenyl-N-tolylamino, N,N-ditolylamino, N-methyl-N-phenylamino, N,N-dianisolylamino, N-mesityl-N-phenylamino, N,N-dimesitylamino, N-phenyl-N-(4-tert-butylphenyl)amino, and N-phenyl-N-(4-trifluoromethylphenyl)amino.

If the substituent of the aromatic hydrocarbon group is an aromatic hydrocarbon group, examples of the aromatic hydrocarbon group include those cited as the aromatic hydrocarbon groups that can be the R₁ to R₁₆. Phenyl, naphthyl, fluorenyl and biphenyl are advantageous, and phenyl is more advantageous.

### Characteristic Features of the Metal Complex Compound

The metal complex compound expressed by general formula [1] is more stable than known alkali metal salts and alkali metal complexes used in organic light-emitting elements. Known alkali metal salts and alkali metal complexes can absorb water to hydrate or ionize, and are thus unstable.

According to the Hard and Soft Acids and Bases (HSAB) principle, alkali metal ions are hard acids and reactive with water that is a hard base. This is the reason why alkali metal salts are unstable.

If a compound reactive with water is used in an organic light-emitting element, water in the air can cause dark spots and property changes, such as voltage increase, during the manufacturing process or operation. The metal complex compound of general formula [1] has the following characteristics and is therefore suitable for use in organic light-emitting elements.

1. The metal complex compound contains sodium or potassium, which is an alkali metal having a high ability to inject electrons from an electrode.
2. The ligand of the metal complex compound is less soluble in water.
By using such a metal complex compound, a stable organic light-emitting element can be achieved.

The above characteristics 1 and 2 will be further described in detail.

1. The metal complex compound of general formula [1] exhibits a high electron injection property because of the presence of an alkali metal, sodium or potassium. Sodium and potassium are more stable than the other alkali metals. Alkali metals have high electron injection properties, but tend to change into cations because of the outermost shell thereof has only one electron. Accordingly, alkali metals are reactive with other molecules including water. As an alkali metal has a larger atomic radius, the ionization energy of the alkali metal decreases. Accordingly, as an alkali metal has a larger atomic radius, the reactivity of the alkali metal with other molecules increases. Hence, sodium and potassium, which have smaller atomic radius than the other alkali metals, are more stable.

The first ionization energy of alkali metals are as follows: Li: 520.2 kJ·mol⁻¹; Na: 495.8 kJ·mol⁻¹; K: 418.8 kJ·mol⁻¹; Rb: 403 kJ·mol⁻¹; Cs: 375.7 kJ·mol⁻¹.

On the other hand, the electron injection property of a metal can increase as the ionization energy of the metal is lower. Sodium and potassium have lower ionization energies than lithium, and are therefore more suitable to reduce the driving voltage of organic light-emitting elements.

2. The metal complex compound of general formula [1] is less reactive with water and is accordingly less soluble in water. The reactivity of a complex with water depends on the unshared electron pairs in the ligand. The presence of an unshared electron pair produces a polar portion in the molecule. This can cause hydration.

Atoms having an unshared electron pair include nitrogen and oxygen. For example, while benzene and naphthalene do not dissolve in water, pyridine, pyrazole, and imidazole dissolve in water. Pyridine, pyrazole and imidazole have unshared electron pairs.

The metal complex compound of general formula [1] does not have any unshared electron pairs because the unshared electron pairs in the ligands are all used for coordination bonds. In other words, the metal complex compound of general formula [1] is less soluble in water because of the ligands with no unshared electron pairs.

Some of the atoms having an unshared electron pair, such as the oxygen atom of the ether group and the fluorine atom, however have a low affinity for water.

The stability to water of the metal complex compound was examined. A deposition film was formed to a thickness of 100 nm on a glass substrate, and water was dropped on the deposition film. After 5 minutes, the state of the film was measured with a thickness profiler (Alpha-Step). Also, the stability to water of lithium fluoride and cesium fluoride, which are generally used as an electron injection material, were examined for comparison. The results are shown in Table 1.

TABLE 1

| | | After 5 min |
|---|---|---|
| Compound 1 (A1) | 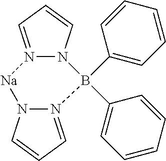 | Not changed |
| Compound 2 (A14) | 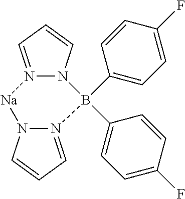 | Not changed |
| Compound 3 (D1) | 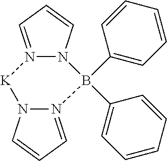 | Not changed |
| Compound 4 (D14) | 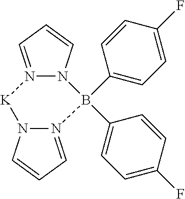 | Not changed |
| Comparative | LiF | Dissolved |
| Compound 1 | | |
| Comparative | CsF | Dissolved |
| Compound 2 | | |

The films of alkali metal salts, that is, lithium fluoride and cesium fluoride, were dissolved in water immediately after being immersed in water. On the other hand, the compounds according to general formula [1] were not dissolved in water and show hydrophobicity. By using a metal complex compound expressed by general formula [1] in an organic light-emitting element, the organic light-emitting element can be stable.

### Exemplary Metal Complex Compounds

Structural formulas exemplary metal complex compounds expressed by general formula [1] are shown below:

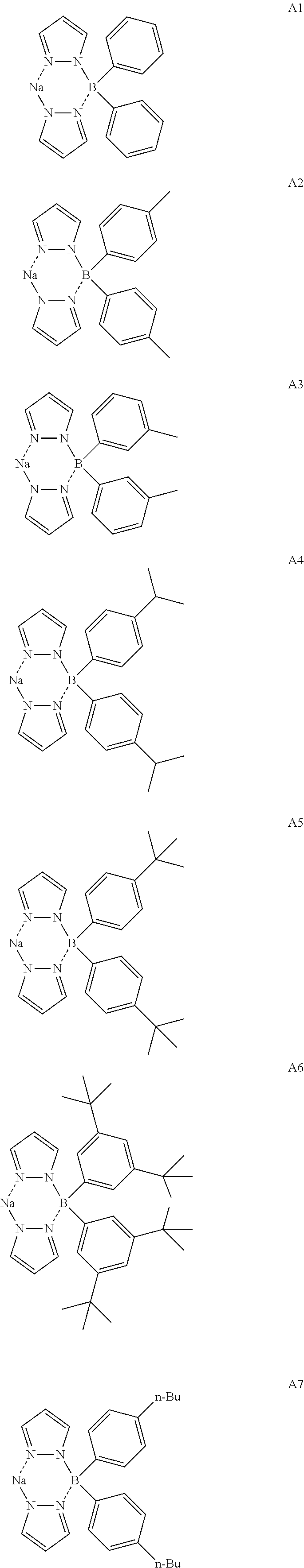

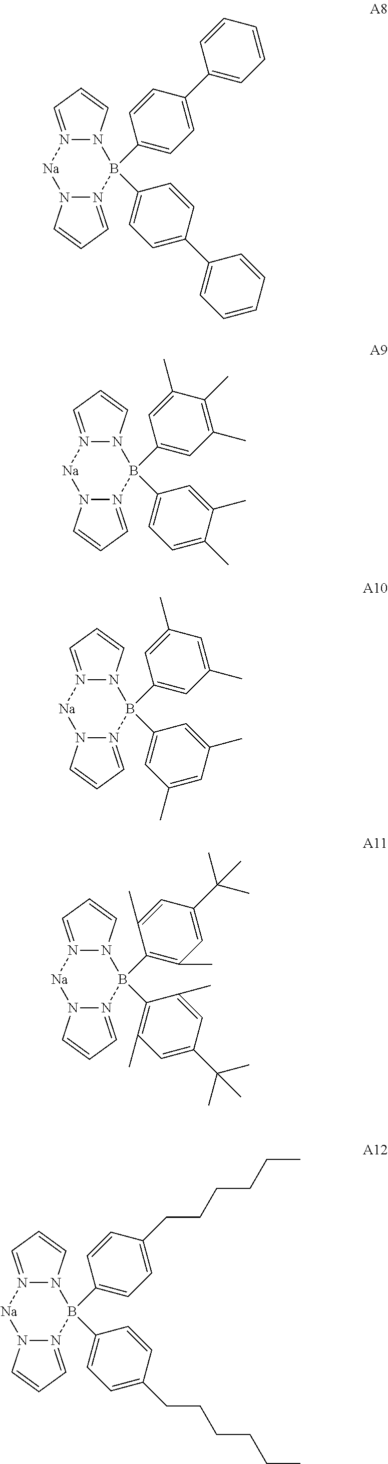

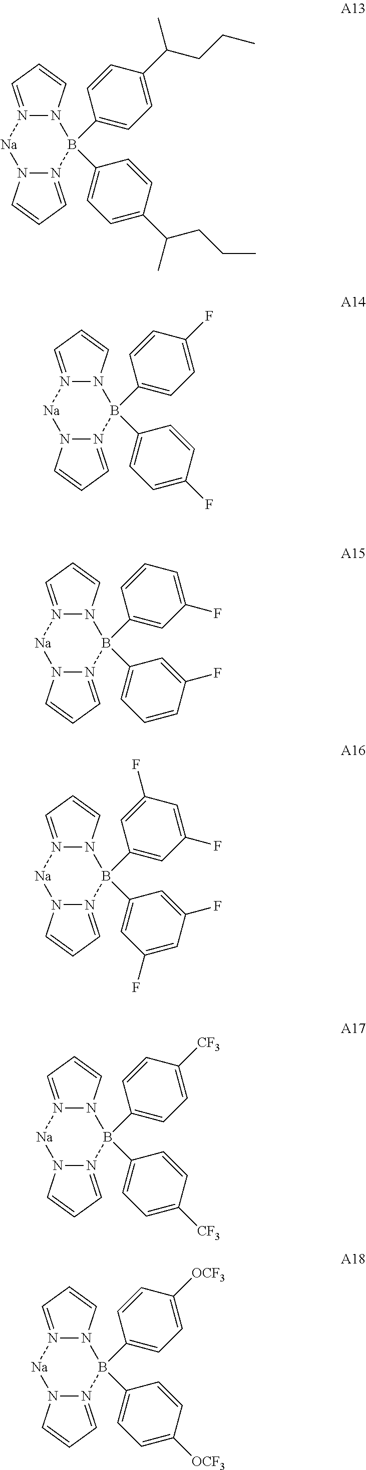

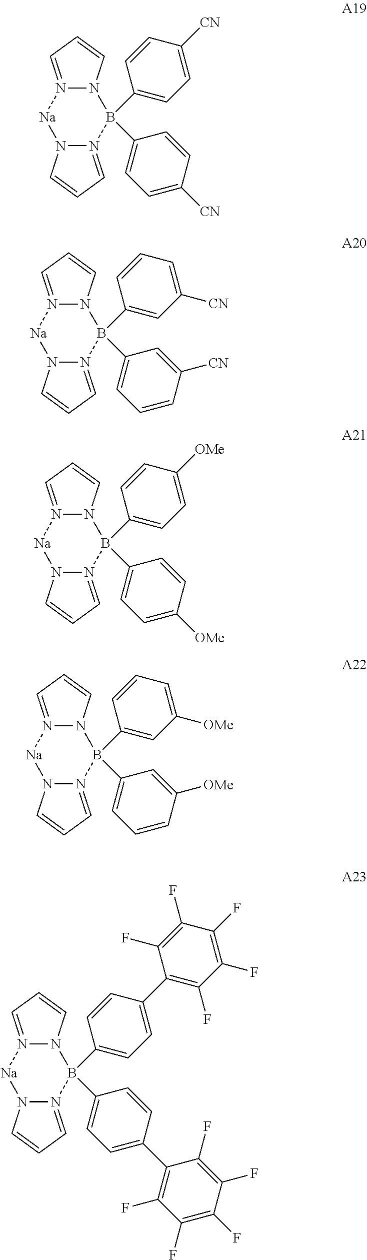

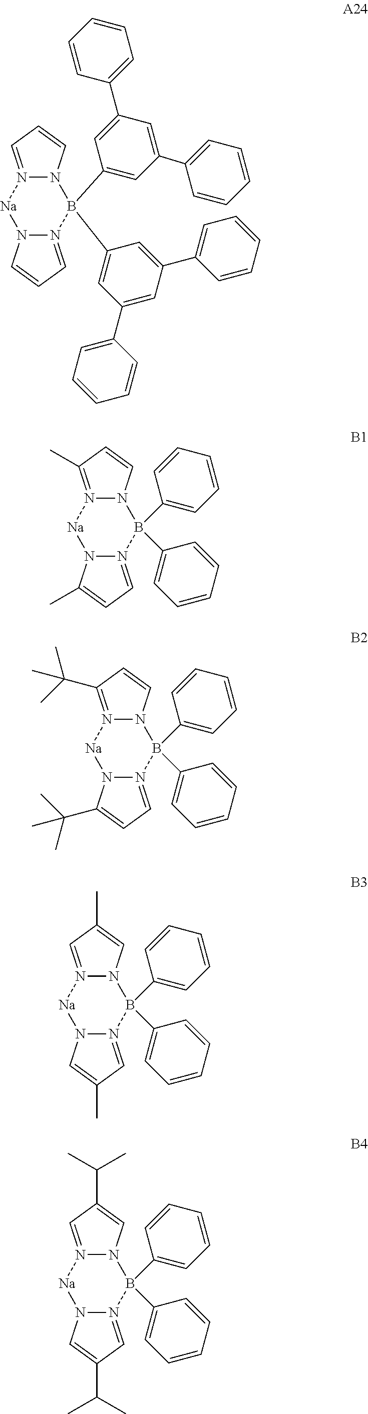

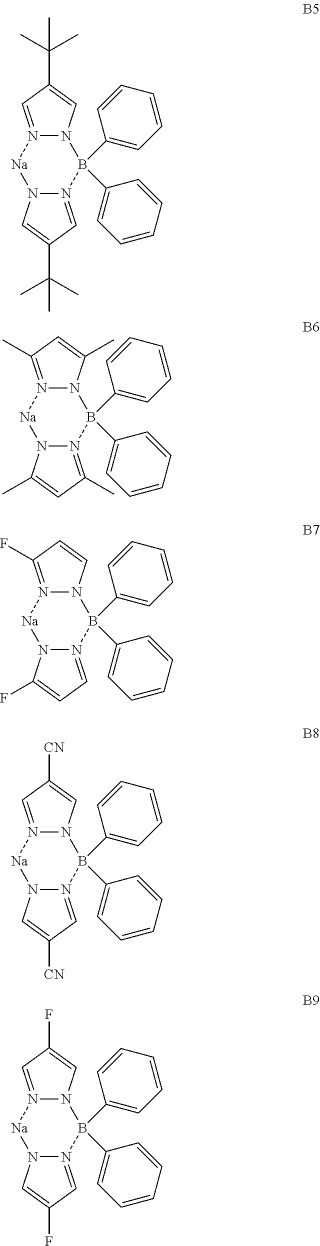

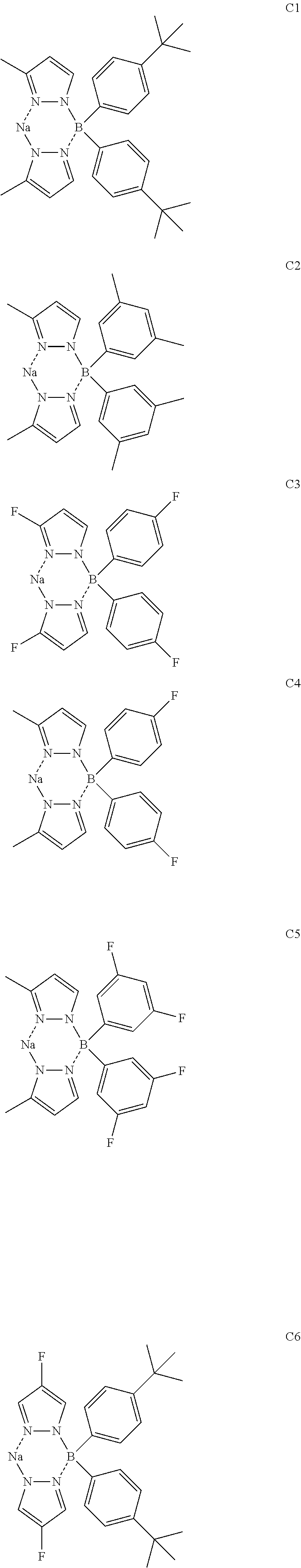

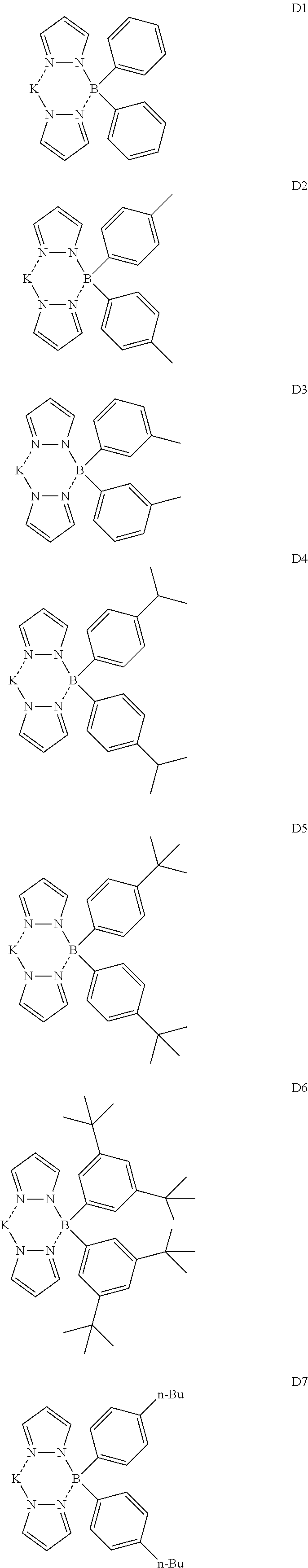

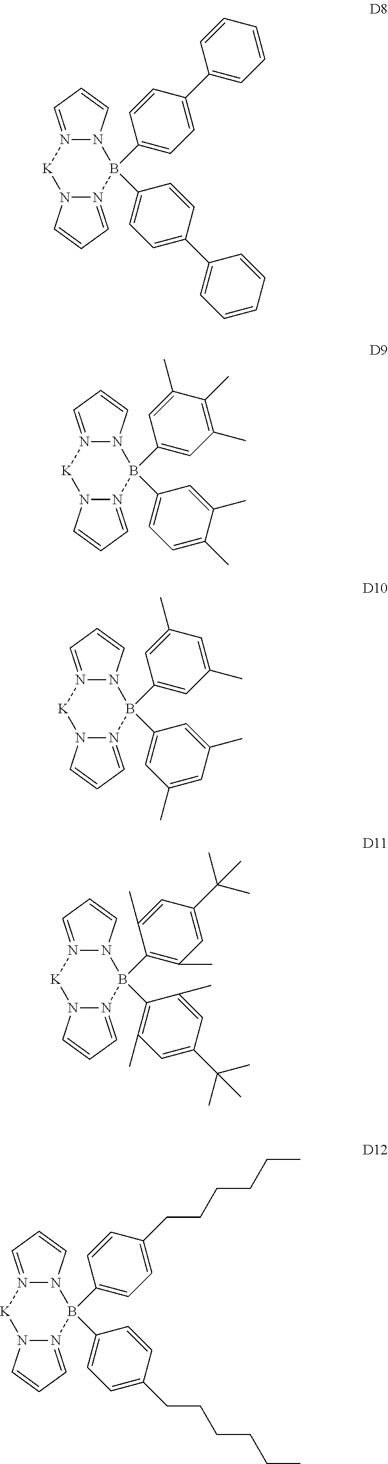

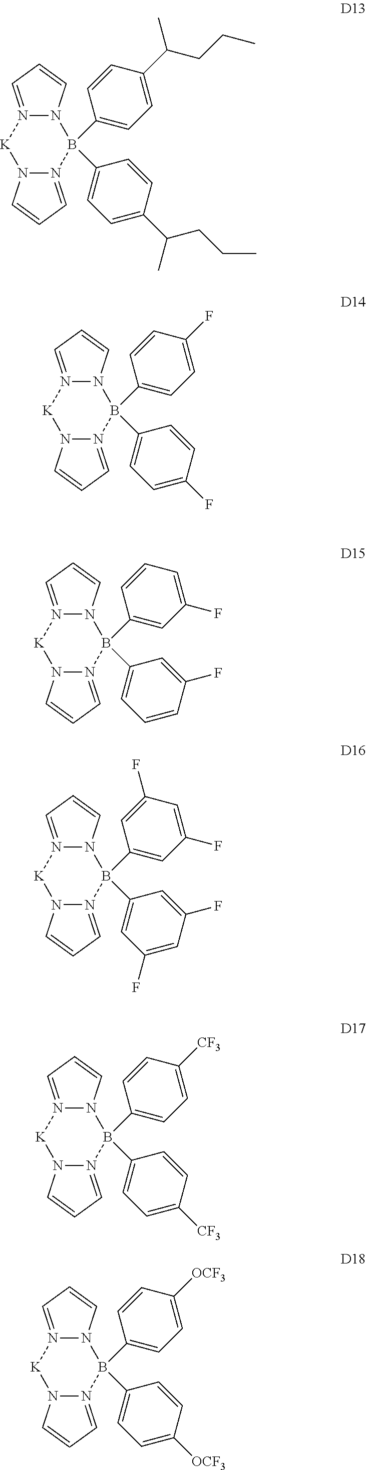

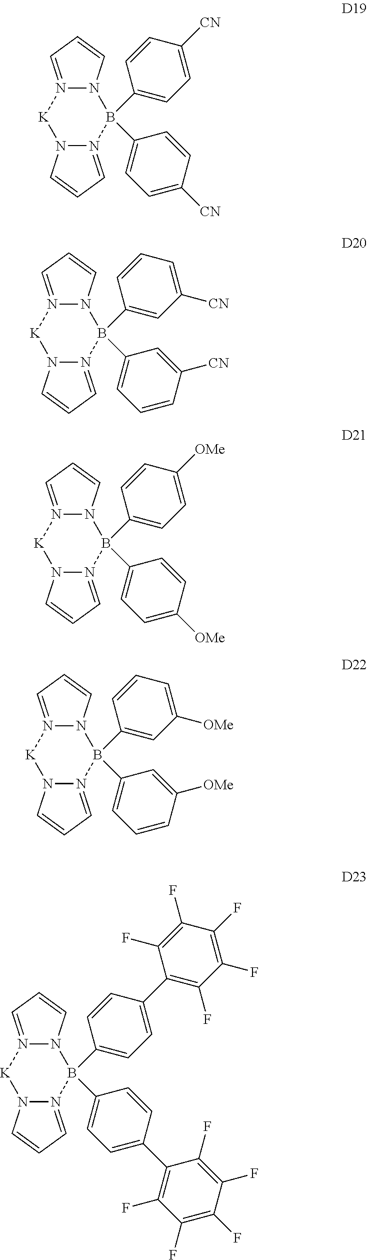

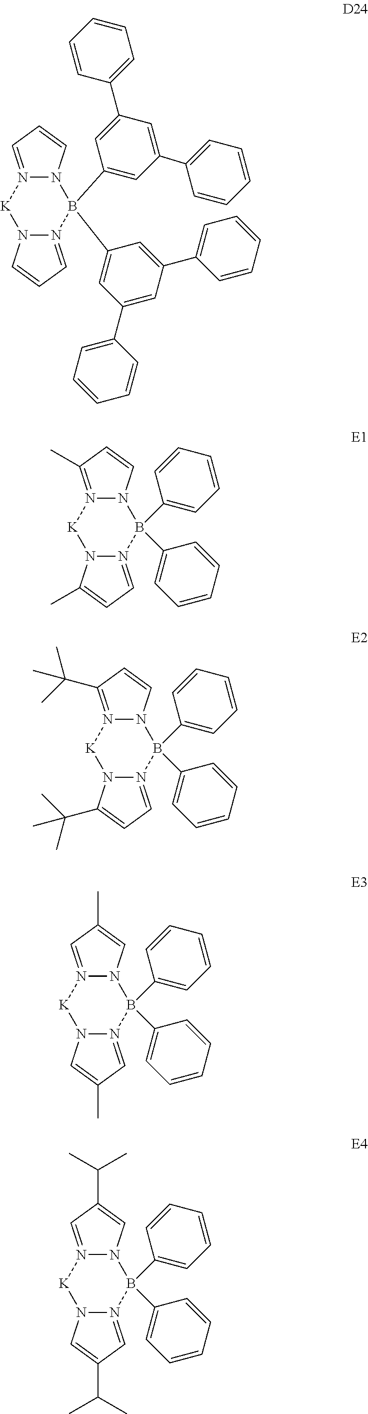

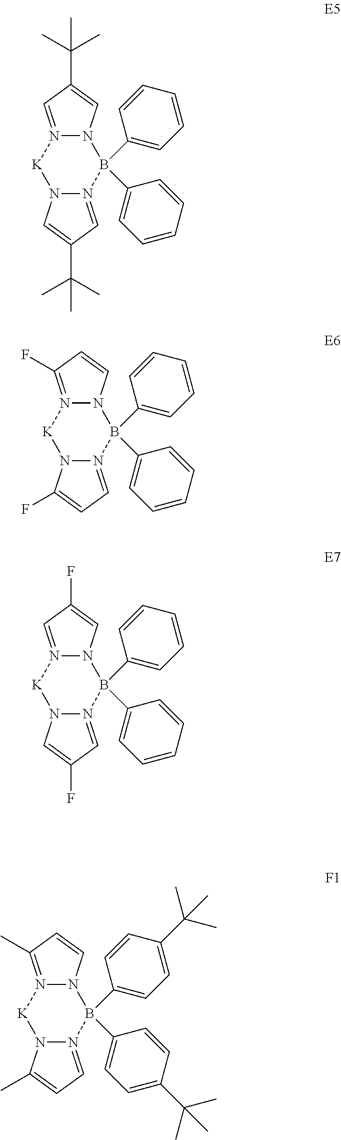

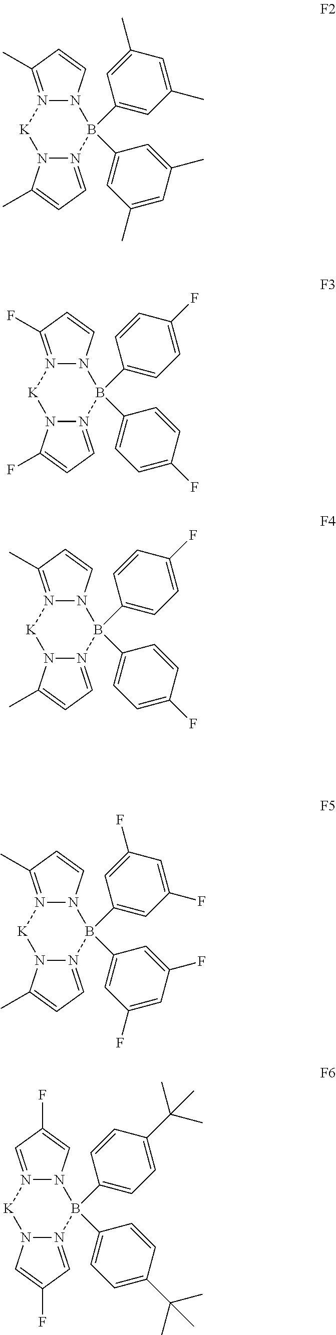

Groups A and D of the exemplary compounds are constituted of compounds in which the pyrazole groups bound to sodium or potassium are not substituted. Hence, R1 to R6 in general formula [1] are all hydrogen atoms. The intermolecular interaction of the metal complex compounds in Group A is small. Accordingly, these compounds are likely to sublimate when being deposited. Also, the bonding between the sodium or the potassium and the pyrazole groups advantageously has a high stability. Fluorine may be introduced to the compound to reduce the sublimation temperature. Also, if the phenyl groups are substituted, the crystallinity of the compound is reduced and the crystallizing of the compound is prevented when an organic light-emitting element is produced.

Group B and E of the exemplary compounds are constituted of compounds in which the pyrazole groups bound to sodium or potassium are substituted. The metal complex compounds in which the sodium or potassium is surrounded by substituents are expected to have higher stability. The substituents can reduce the crystallinity of the compound, thus preventing the compound from crystallizing when the organic light-emitting element is produced.

Groups C and F of the exemplary compounds are constituted of compounds in which both the pyrazole groups and the phenyl groups are substituted. The metal complex compounds in which the sodium or potassium is surrounded by substituents are expected to have high stability. The presence of the substituents introduced to the pyrazole and phenyl groups reduce the crystallinity of the compound effectively. The compounds of Group C are suitable for the use in organic light-emitting elements formed by coating.

Advantageously, R₇, R₁₁, R₁₂ and R₁₆ of the metal complex compound are all hydrogen atoms.

It is also advantageous that R₈ to R₁₀ and R₁₃ to R₁₅ are each selected from the group consisting of halogen atoms, alkyl groups, and substituted or unsubstituted aromatic hydrocarbon groups.

If the metal complex compound is used in a layer in contact with the cathode of an organic light-emitting element, all the R₁ to R₁₆ in general formula [1] may be hydrogen.

### Synthesis of Metal Complex Compound

A process for synthesizing the metal complex compound of general formula [1] will now be described. The metal complex compound may be synthesized according to, for example, the following reaction scheme:

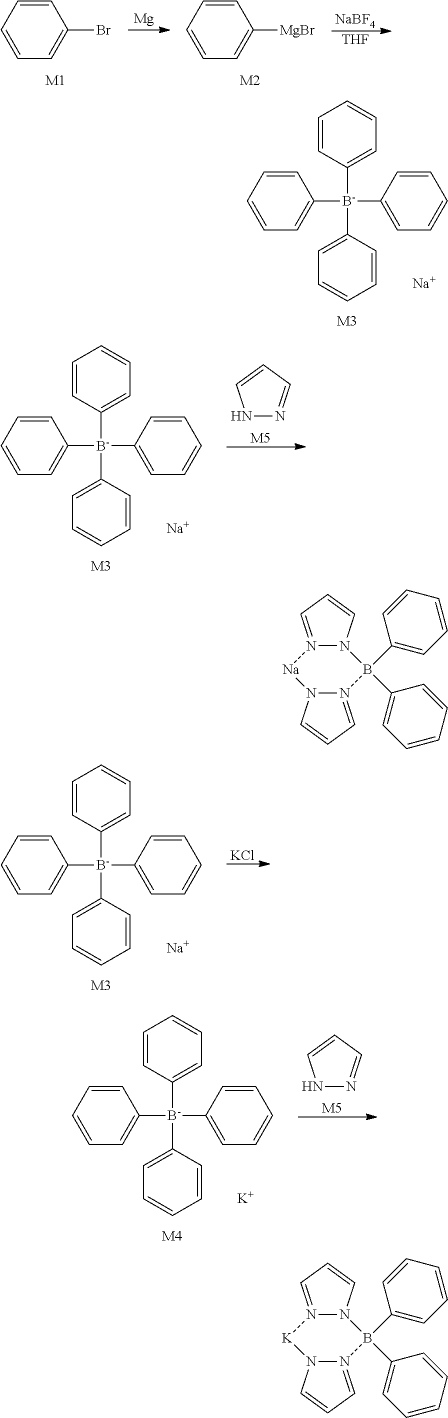

By substituting a hydrogen atom of bromobenzene M1 or pyrazole M5 with a species, such as alkyl, aromatic hydrocarbon, heteroaryl, fluorine, methoxy, or cyano, various forms of the metal complex compound can be produced. If Compound M2, M3 or M4 is commercially available, the metal complex compound may be synthesized from M2, M3 or M4.

The metal complex compound is synthesized as shown in the above scheme.

It can be checked by X-ray structural analysis, ICP, NMR, MAS or the like whether the metal complex compound has been synthesized. These methods can also show the structure of the metal complex compound.

The compounds used in the organic light-emitting element can be analyzed by, for example, mass spectrometry, such as time-of-flight secondary ion mass spectrometry (TOF-SIMS). Alternatively, NMR or IR may be used.

The organic light-emitting element according to an embodiment includes an anode and a cathode, and a luminescent layer between the anode and the cathode, and further includes an organic compound layer in contact with the cathode between the cathode and the luminescent layer. The organic compound layer contains a metal complex compound expressed by the following general formula [1]. The organic compound layer in contact with the cathode may be called an electron injection layer or an electron transport layer.

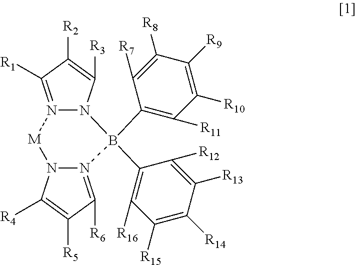

In general formula [1], M represents sodium or potassium. R₁ to R₁₆ each represent a hydrogen atom or a substituent. The substituent is a species selected from the group consisting of halogen atoms, the cyano group, alkyl groups that may be substituted with a halogen atom, alkoxy groups that may be substituted with a halogen atom, and aromatic hydrocarbon groups.

The aromatic hydrocarbon groups may be substituted with at least one species selected from the group consisting of halogen atoms, substituted or unsubstituted alkyl groups, substituted or unsubstituted alkoxy groups, substituted amino groups, and substituted or unsubstituted aromatic hydrocarbon groups.

The organic light-emitting element may have any one of the following multilayer structure including one or more organic compound layers on a substrate. The layer of the organic compound layers containing a luminescent material is the luminescent layer.

(1) anode/luminescent layer/cathode
(2) anode/hole transport layer/luminescent layer/electron transport layer/cathode
(3) anode/hole transport layer/luminescent layer/electron transport layer/electron injection layer/cathode
(4) anode/hole injection layer/hole transport layer/luminescent layer/electron transport layer/cathode
(5) anode/hole injection layer/hole transport layer/luminescent layer/electron transport layer/electron injection layer/cathode
(6) anode/hole transport layer/electron blocking layer/luminescent layer/hole blocking layer/electron transport layer/cathode

These are merely basic structures and are not intended to limit the structure of the organic light-emitting element using the metal complex compound of general formula [1].

The organic light-emitting element may take various structures. For example, the organic light-emitting element of an embodiment may further include an insulating layer between an electrode and an organic compound layer, or may have an adhesion layer or an interference layer. The electron transport layer or the hole transport layer may be composed of two layers having different ionization potentials, or the luminescent layer may be composed of two layers containing different luminescent materials.

The light-emitting element may be of a bottom emission type that emits light through the substrate, of a top emission type that emits light through the opposite side to the substrate, or of a type that emits light through both sides.

Among the above structures, structure (6), which includes an electron blocking layer and a hole blocking layer, is advantageous. Structure (6) enables holes and electrons to be confined in the luminescent layer without leaking the carriers, thus achieving an organic light-emitting element having high emission efficiency.

In the organic light-emitting element of an embodiment, the organic compound layer containing the metal complex compound expressed by general formula [1] acts as the electron injection layer or electron transport layer in contact with the cathode.

The layer in contact with the cathode contains the metal complex compound.

More specifically, although the metal complex compound of general formula (1) may be contained in any of the hole injection layer, the hole transport layer, the electron blocking layer, the luminescent layer, the hole blocking layer, the electron transport layer and the electron injection layer, the organic compound layer in contact with the cathode must contain the metal complex compound.

The organic compound layer in contact with the cathode may be made of only the metal complex compound, or may contain the metal complex compound and a second compound different from the metal complex compound. The second compound may be an organic compound or an inorganic compound. The content of the second compound in the organic compound layer in contact with the cathode may be more than 0% by weight and 80% by weight or less, preferably 50% by weight, relative to the total weight (100% by weight) of the organic compound layer.

If the electron injection layer is the layer containing the metal complex compound of general formula [1] and the second compound, the metal complex compound may be used as the host or guest of the electron injection layer. Alternatively, the metal complex compound may be used as an assist material in the electron injection layer.

The host mentioned herein refers to the compound accounting for the highest percentage, on a weight basis, of the constituents in the electron injection layer. The guest mentioned herein refers to a compound accounting for a percentage lower than the host on a weight basis in the electron injection layer. The assist material mentioned herein refers to a compound accounting for a percentage lower than the host on a weight basis and different from the guest in the electron injection layer. The assist material may be referred to as a second host.

As described above, the organic light-emitting element may further include a hole injection layer, a hole transport layer, an electron blocking layer, a hole blocking layer, an electron transport layer, an electron injection layer, or any other layer in addition to the anode, the cathode, the luminescent layer, and the organic compound layer, different from the luminescent layer, in contact with the cathode. Also, the luminescent layer may be composed of a single layer or include a plurality of layers.

Although a hole blocking layer refers generally to a layer that blocks holes, the hole blocking layer used herein refers to a layer adjacent to the luminescent layer.

The luminescent layer of the organic light-emitting element of an embodiment may contain a plurality of constituents. The constituents are classified into the main constituent and sub constituents. The main constituent refers to the compound accounting for the highest percentage, on a weight basis, of the constituents of the luminescent layer. And maybe called a host material.

The sub constituents are compounds other than the main constituent. Sub constituents may be called a guest material (dopant), a luminescence assist material, or a charge injection material. The luminescence assist material and the charge injection material may be organic compounds having the same structure or different structures. These may be called host material 2 to distinguish from the guest material.

The guest material in the luminescent layer is a compound that functions for the major light emission. On the other hand, the host material is a compound present as the matrix of the luminescent layer around the guest material, and functions mainly to transport carriers and supply excitation energy to the guest material.

The guest material content in the luminescent layer may be in the range of 0.01% by weight to less than 50% by weight, such as in the range of 0.1% by weight to 20% by weight, relative to the total weight of the materials of the luminescent layer. The guest material content is desirably 10% by weight or less from the viewpoint of preventing concentration quenching. The guest material may be present uniformly throughout the layer made of the host material, or may be present with a concentration gradient. Alternatively, the layer of the host material may partially contain the guest material so as to have a portion not containing the guest material.

The luminescent layer of the organic light-emitting element of an embodiment may be composed of a single layer or have a multilayer structure. The luminescent layer may contain two or more luminescent materials. The multilayer structure refers to a state where different luminescent layers are formed one on top of another.

The organic light-emitting element may emit light of primary color, such as blue, green, or red, or white or an intermediate color.

In an embodiment, an organic compound layer of the organic light-emitting element includes a luminescent portion containing a plurality of luminescent materials. One or some of the plurality of luminescent materials may emit light different from the other luminescent materials, and the element containing these luminescent materials may emit white light.

The organic light-emitting element may include a plurality of luminescent layers, and one or some of the plurality of luminescent layers may emit light having a different color from the color of light emitted from the other luminescent layers. The luminescent layer that emits such a different color may be called a second luminescent layer.

In an embodiment, the organic light-emitting element may be configured so that the colors of light emitted from the plurality of luminescent layers are mixed to emit white light.

The plurality of luminescent layers may be formed in the direction from the anode to the cathode or may be arranged in a lateral manner. To arrange the luminescent layers in a lateral manner means that each of the luminescent layers is disposed so as to be in contact with the same organic compound layer.

The metal complex compound may be used in combination with a luminescent material of a low-molecular-weight compound or a polymer, a hole-injecting compound, a hole-transporting compound, a compound that can act as a host, a luminescent compound, an electron-injecting compound, or an electron-transporting compound, if necessary.

These compounds will now be described.

The hole-injecting or transporting material desirably has so high a hole mobility as facilitates hole injection from the anode and enables the injected holes to be transported to the luminescent layer. From the viewpoint of preventing the crystallization or any other deterioration of the material in the organic light-emitting element, the hole-injecting or transporting material desirably has a high glass transition temperature.

Low-molecular-weight or polymeric hole-injecting or transporting materials include triarylamine derivatives, arylcarbazole derivatives, phenylenediamine derivatives, stilbene derivatives, phthalocyanine derivatives, porphyrin derivatives, poly(vinyl carbazole), polythiophene, and other conductive polymers. The hole-injecting or transporting material is also used suitably in the electron blocking layer.

Exemplary compounds that can be used as the hole-injecting or transporting material include, but are not limited to:

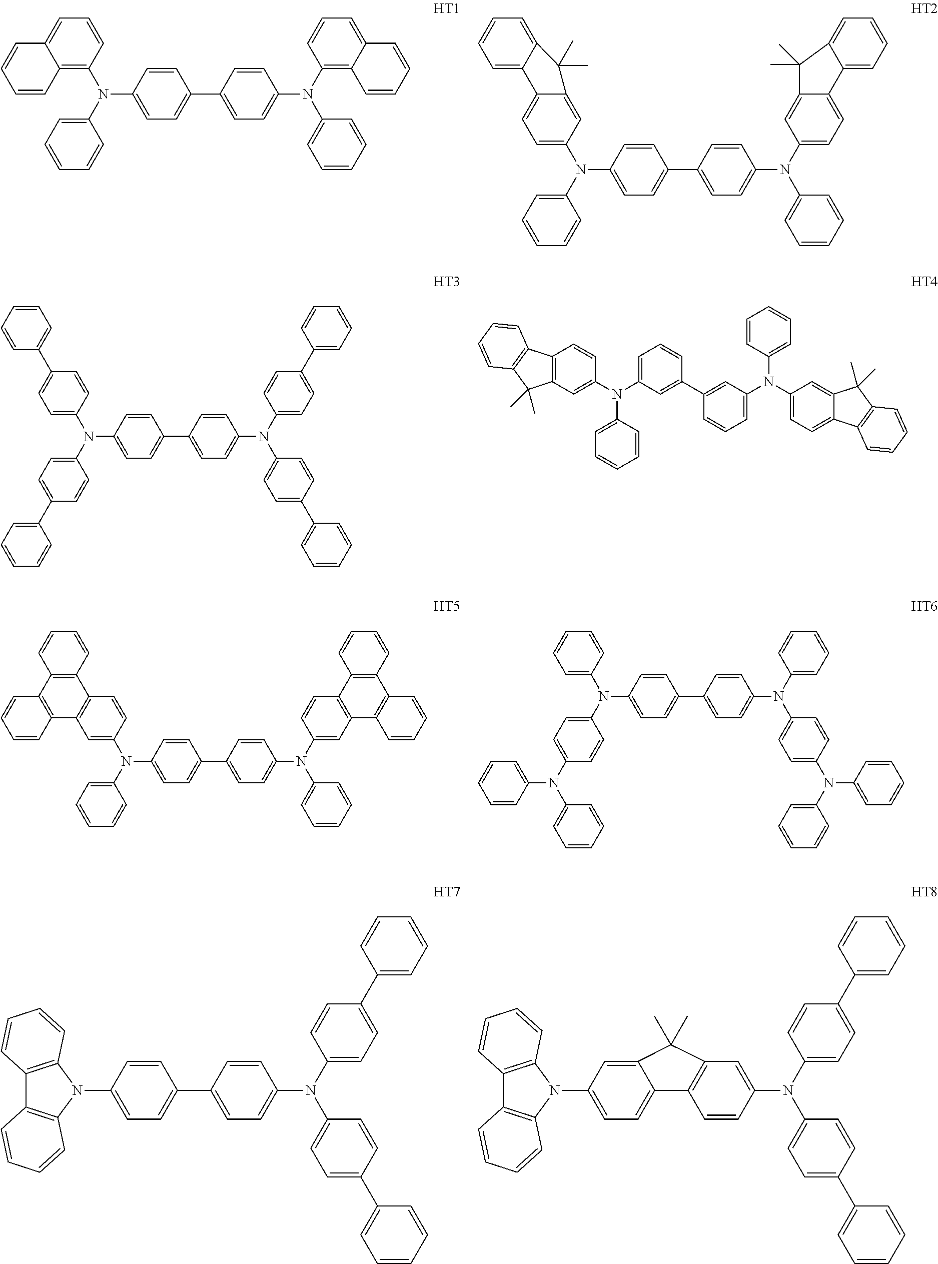

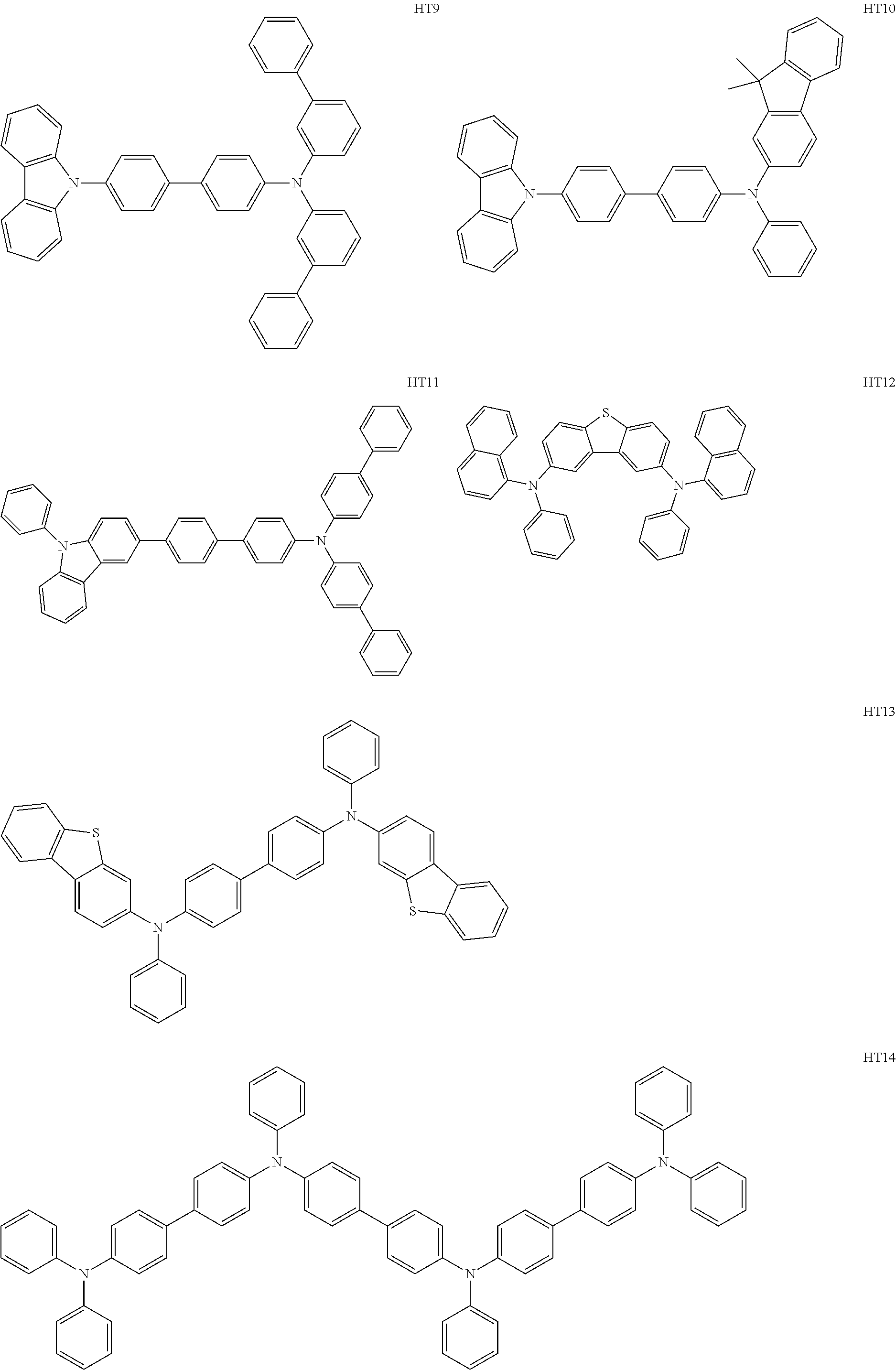

Luminescent materials involved in light emission include condensed ring compounds (such as fluorene derivatives, naphthalene derivatives, pyrene derivatives, perylene derivatives, tetracene derivatives, anthracene derivatives, and rubrene), quinacridone derivatives, coumarin derivatives, stilbene derivatives, and tris(8-quinolinolate) aluminum and other organic aluminum complexes, iridium complexes, platinum complexes, rhenium complexes, copper complexes, europium complexes, ruthenium complexes, and polymer derivatives such as poly(phenylene vinylene) derivatives, polyfluorene derivatives, and polyphenylene derivatives.

Exemplary compounds that can be used as the luminescent material include, but are not limited to:

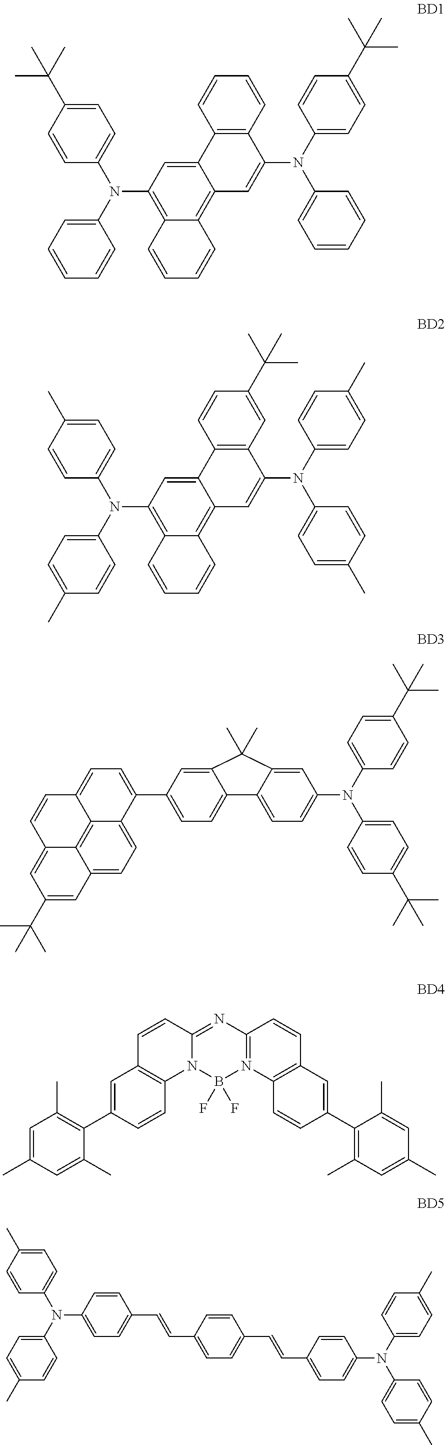

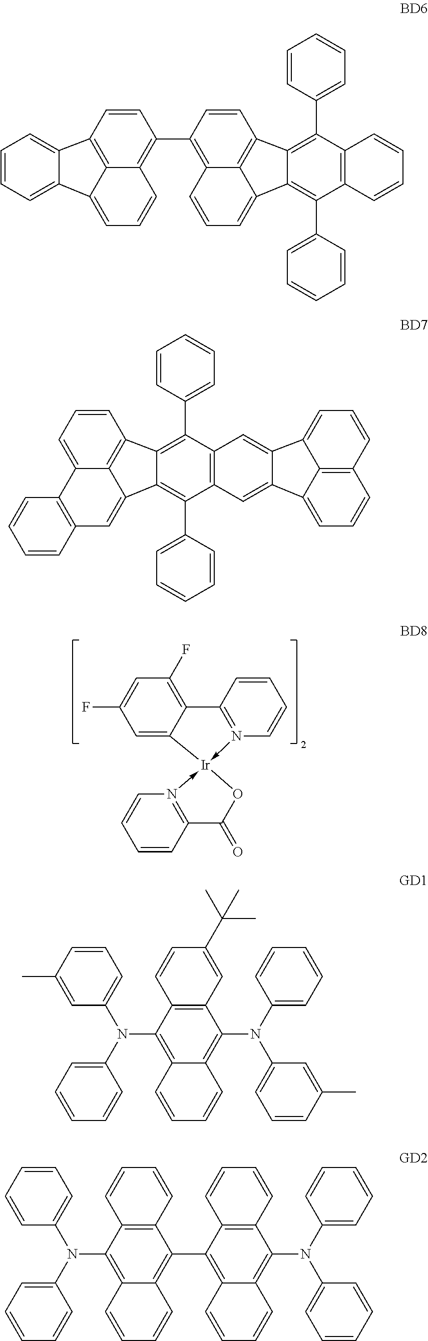

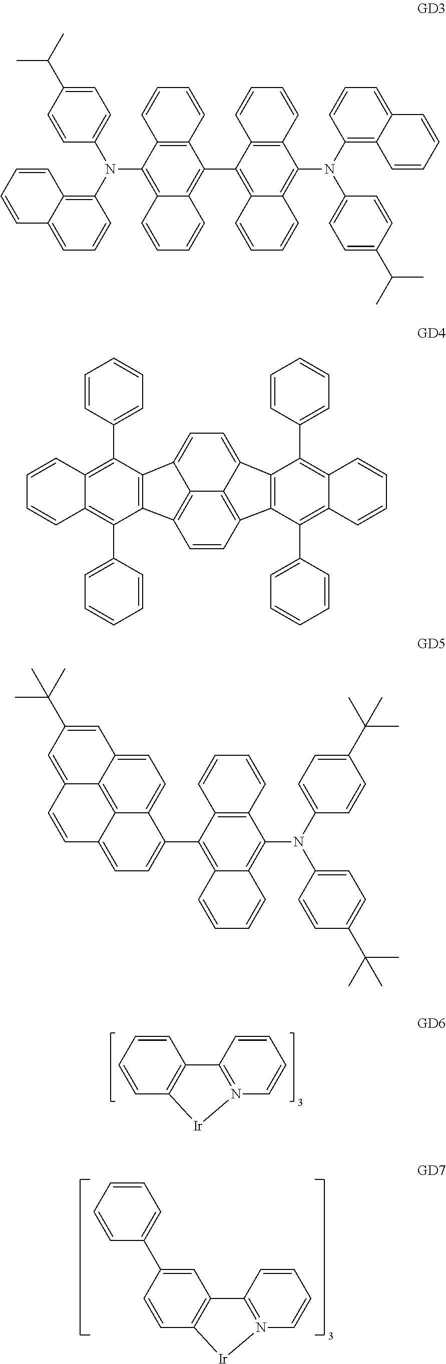

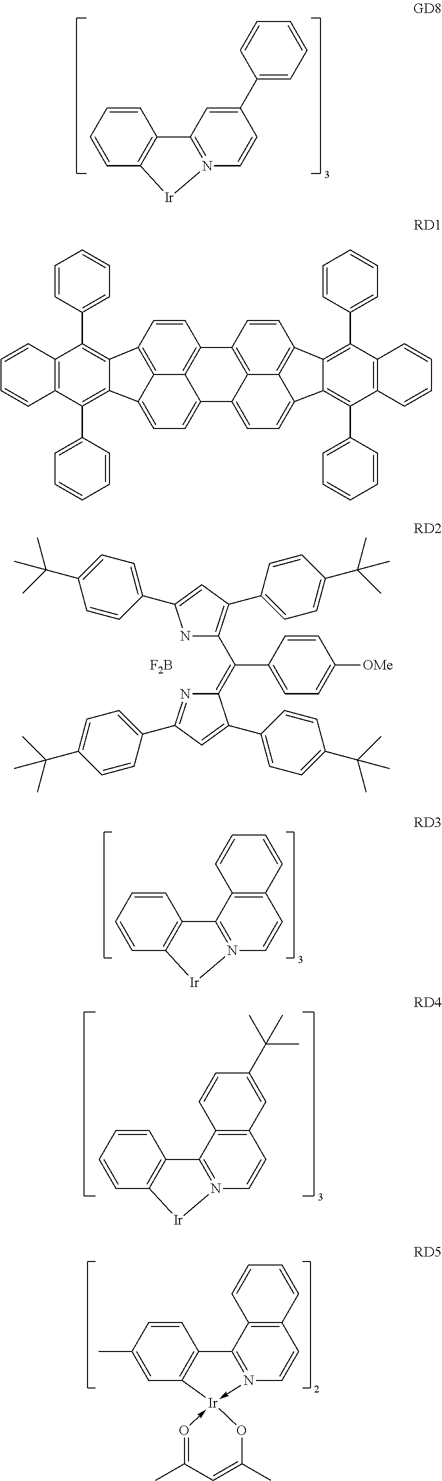

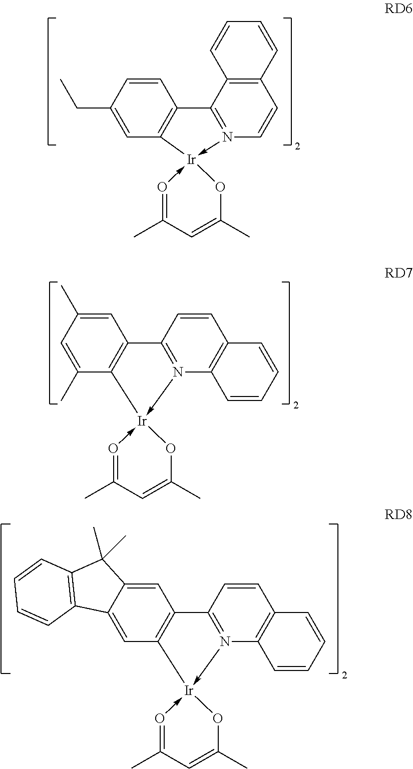

Host or luminescence assist materials that can be used in the luminescent layer include aromatic hydrocarbons and derivatives thereof, carbazole derivatives, dibenzofuran derivatives, dibenzothiophene derivatives, organic aluminum complexes such as tris(8-quinolinolate) aluminum, and organic beryllium complexes.

Exemplary compounds that can be used as the host or luminescent assist material include, but are not limited to:

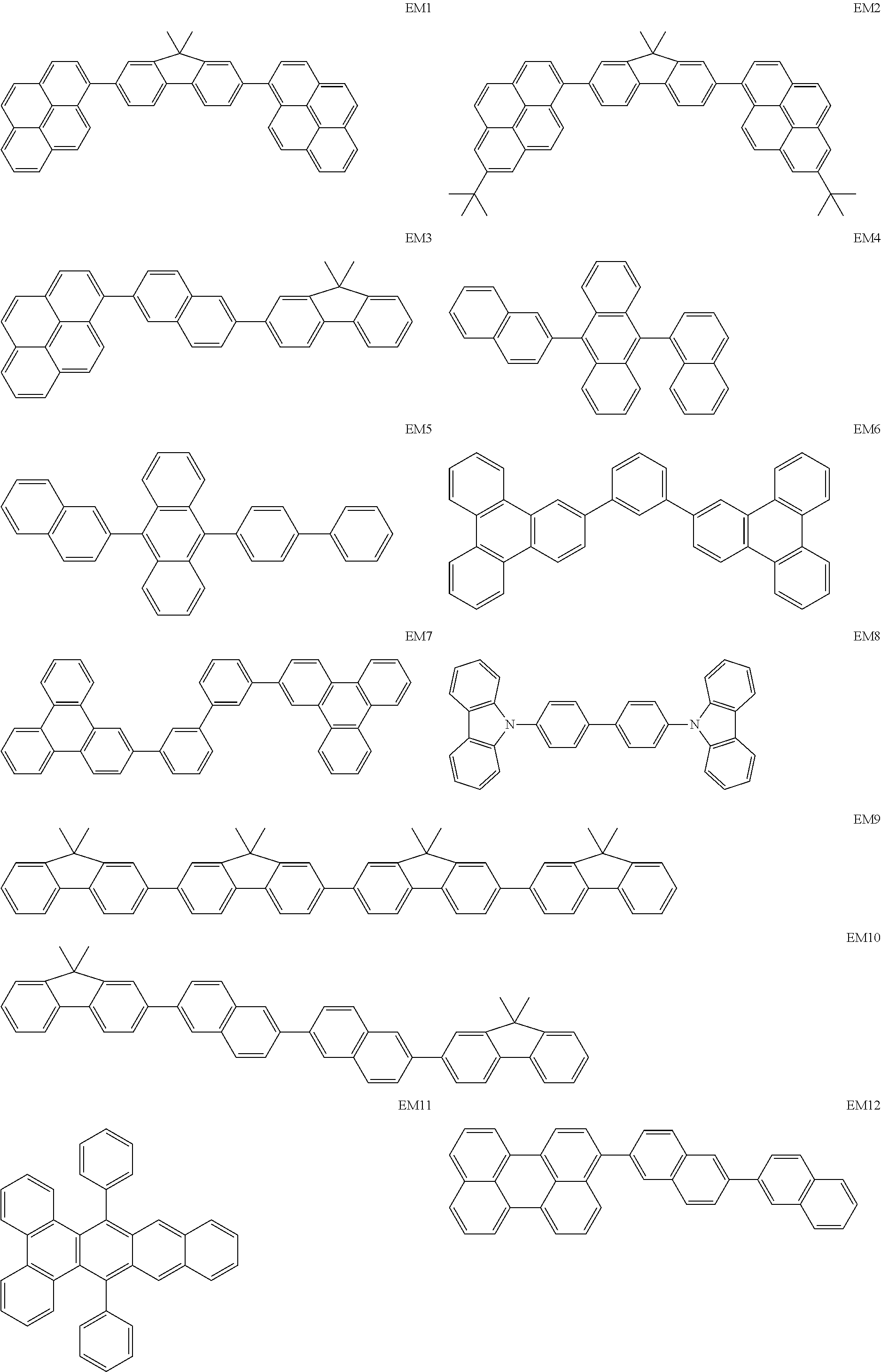

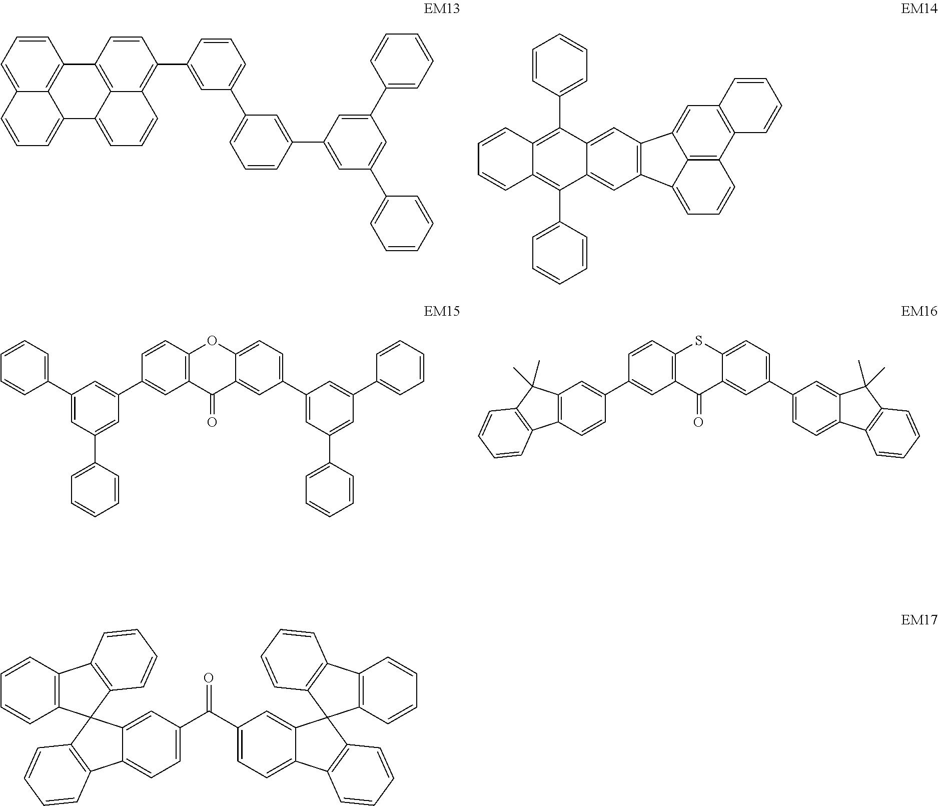

If an electron transport material is used in combination with the metal complex compound of general formula [1], the electron transport material can be selected from the electron-transporting materials capable of transporting electrons injected from the cathode to the luminescent layer in view of the balance with the hole mobility of the hole-transporting material. Electron-transporting materials include oxadiazole derivatives, oxazole derivatives, pyrazine derivatives, triazole derivatives, triazine derivatives, quinoline derivatives, quinoxaline derivatives, phenanthroline derivatives, organic aluminum complexes, and condensed ring compounds (such as fluorene derivatives, naphthalene derivatives, chrysene derivatives, and anthracene derivatives). These electron-transporting materials are also used suitably in the hole blocking layer.

Exemplary compounds that can be used as the electron-transporting material or electron-injecting material include, but are not limited to:

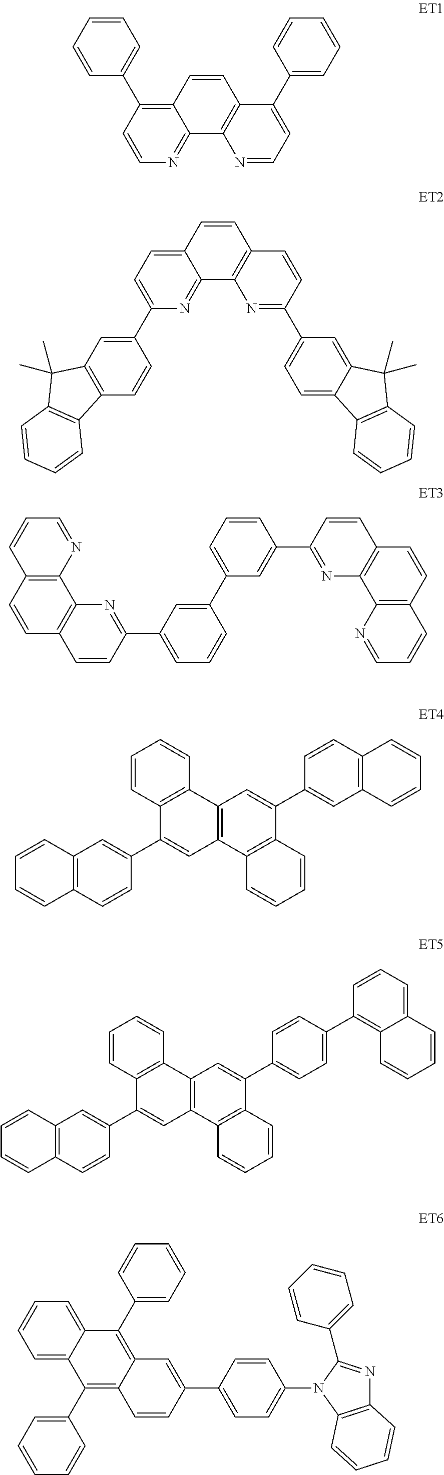

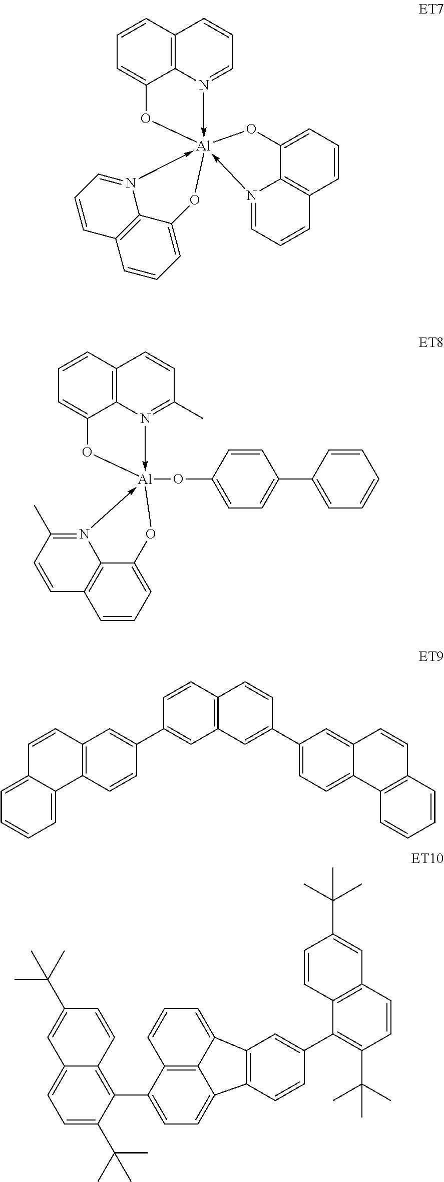

The anode is desirably made of a compound having a work function as high as possible. Such materials include simple metals such as gold, platinum, silver, copper, nickel, palladium, cobalt, selenium, vanadium, and tungsten, and alloy thereof; and metal oxides such as tin oxide, zinc oxide, indium oxide, indium tin oxide (ITO), and zinc indium oxide. Electrically conductive materials can also be used, such as polyaniline, polypyrrole, and polythiophene.

These anode materials may be used singly or in combination. The anode may be composed of a single layer or a plurality of layers.

On the other hand, the cathode is desirably made of a compound having a low work function. Examples of the cathode material include alkali metals, such as lithium; alkaline-earth metals, such as calcium; and other simple metals, such as aluminum, titanium, manganese, silver, lead, and chromium. Alloys of these simple metals may be used. Examples of such an alloy include magnesium-silver, aluminum-lithium, and aluminum-magnesium. A metal oxide, such as indium tin oxide (ITO), may be used. These cathode materials may be used singly or in combination. The cathode may be composed of a single layer or a plurality of layers.

The organic compound layers (hole injection layer, hole transport layer, electron blocking layer, luminescent layer, hole blocking layer, electron transport layer, and electron injection layer) may be formed as below.

The organic compound layers of the organic light-emitting element may be formed in a dry process performed by, for example, vacuum vapor deposition, ionized vapor deposition, sputtering, or using plasma. Alternatively, the organic compound layers may be formed in a wet process performed by a known coating method using a material dissolved in a solvent, such as spin coating, dipping, a cast method, Langmuir-Blodgett (LB) method, or an ink-jet method.

Layers formed by vacuum evaporation, solution coating or the like are unlikely to crystallize and are thus superior in stability with time. For the coating method, an appropriate binder resin may be used in combination.

Examples of the binder resin include, but are not limited to, polyvinylcarbazole resin, polycarbonate resin, polyester resin, ABS resin, acrylic resin, polyimide resin, phenol resin, epoxy resin, silicone resin, and urea resin.

These binder resins may be used in the form of homopolymer or copolymer as a single material, or may be used in combination in the form of mixture. Known additives, such as a plasticizer, an antioxidant and an ultraviolet light adsorbent, may be used in addition to the binder resin.

Applications of Organic Light-Emitting Element

The organic light-emitting element may be used as a component of a display device or a lighting device. In addition, the organic light-emitting element may be used in an exposure light source of an electrophotographic image forming apparatus, a back light of a liquid crystal display device, a white light source, or a light-emitting device including a color filter and a white light source.

The color filter transmits at least one color of red, green and blue. The light-emitting device may include a filter for controlling the chromaticity of white light and a white light source in combination.

The display device includes a display portion including the organic light-emitting elements of an embodiment of the application. The display portion includes a plurality of pixels. Each of the pixels includes the organic light-emitting element and an active element connected to the organic light-emitting element.

The active element may be a switching element or an amplifier element that controls the luminance of emitted light. More specifically, the active element may be a transistor.

Either the anode or the cathode of the organic light-emitting element is electrically connected to either the drain or the source electrode of the transistor. The display device can be used as an image display device of a PC or the like.

Alternatively, the display device may be used in an image information processing unit that includes an input portion to which image information is input from an area CCD, a linear CCD, a memory card or the like and an information processing portion adapted to process the inputted information, and that thus displays the inputted information on a display portion.

The display device may be a display portion of an image pickup apparatus or ink jet printer. The display portion functions both as an image output portion on which an image is displayed according to image information input from the outside, and as an operation panel with which information is input to process the image. Also, the display device may be used as a display portion of a multifunction printer. For the use of a display portion, the display device may have a function as a touch panel. The touch panel may be of capacitance, resistive film, or infrared.

The lighting device illuminates, for example, a room. The lighting device may emit white light, neutral white light, or any other color light of the colors from blue to red. Any one of the organic light-emitting elements in the lighting device is the organic light-emitting element of an embodiment of the application. The organic light-emitting element may emit any color light.

In the description herein, white has a color temperature of 4200 K and neutral white has a color temperature of 5000 K. The lighting device may further include a color filter.

The lighting device includes the organic light-emitting element of an embodiment of the application and an AC/DC converter connected to the organic light-emitting element to supply driving power.

The AC/DC converter converts alternating voltage into direct voltage.

The lighting device may include a heat radiation portion that dissipates heat from the light-emitting portion or the circuit to the outside. The heat radiation portion may be a heat sink plate made of a metal having a high thermal conductivity, or may be defined by liquid silicon. The metal having a high thermal conductivity may be a metal containing aluminum. If liquid silicon is used for heat dissipation, the liquid silicon is allowed to flow for convection.

The image forming apparatus according to an embodiment of the present application includes a photosensitive member, a charging member that charges the surface of the photosensitive member, an exposure portion that exposes the photosensitive member, and a developer that develops the electrostatic latent image on the surface of the photosensitive member. The exposure portion includes the organic light-emitting element of an embodiment of the present application.

The exposure portion may be an exposure device including the organic light-emitting element according to an embodiment of the present application. Alternatively, the exposure portion may be an exposure unit including the organic light-emitting element according to an embodiment of the present application. The exposure unit may include a plurality of organic light-emitting elements aligned in a line or arranged so that the entire surface of the exposure unit can emit light.

The metal complex compound of general formula (1) can be used in an organic solar cell, an organic TFT, a fluorescent biometric identification material, a film, a filter, and so forth in addition to the use in the organic light-emitting element.

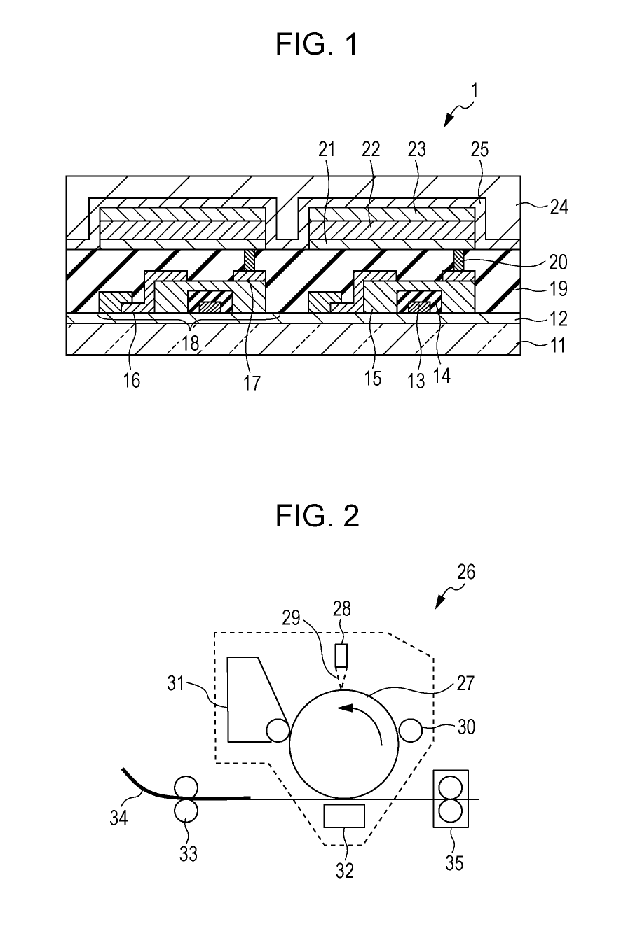

A display device including the organic light-emitting element of an embodiment of the present application will now be described with reference to FIG. 1.

The display device 1 shown in FIG. 1 includes a substrate 11 made of glass or the like, and a moisture-proof layer 12 over the substrate for protect TFT elements or organic compound layers. Each TFT element 18 includes a metal gate electrode 13, a gate insulating film 14, a semiconductor layer 15, a drain electrode 16 and a source electrode 17. An insulating layer 19 is disposed over the TFT elements 18. Each source electrode 17 is connected to the anode 21 of the corresponding organic light-emitting element through a contact hole 20.

The electrical connection from the electrodes (anode, cathode) of the organic light-emitting element to the electrodes (source electrode, drain electrode) of the TFT is not limited to the manner shown in FIG. 1. In other words, either the anode 21 or the cathode 23 of the organic light-emitting element is electrically connected to either the source electrode 17 or the drain electrode 16 of the TFT element 18.

Although the display device 1 shown in FIG. 1 is illustrated as if it had a singly organic compound layer, the organic compound layer 22 may have a plurality of layers. Furthermore, a first protective layer 24 and a second protective layer 25 are disposed over the cathode 23 to suppress the degradation of the organic light-emitting element.

Although the display device 1 shown in FIG. 1 uses transistors as switching elements, metal-insulator-metal (MIM) elements may be used as the switching elements instead of the transistors.

Each transistor of the display device 1 shown in FIG. 1 may be a thin film transistor including an active layer on the insulating surface of the substrate without being limited to a transistor formed in a monocrystalline silicon wafer. The active layer of the thin film transistor may be made of monocrystalline silicon, amorphous silicon, microcrystalline silicon or any other non-monocrystalline silicon, an amorphous oxide semiconductor such as indium zinc oxide (IZO) or indium gallium zinc oxide (IGZO), or a transparent oxide semiconductor. Thin film transistors are referred to as TFT elements.

The transistors in the display device 1 shown in FIG. 1 may be formed in the substrate, which may be made of Si. To be formed in the substrate means that the transistors are formed by working the substrate. In other words, a transistor formed in a substrate implies that the substrate and the transistor are formed in one body.

It depends on definition whether the transistors are formed in the substrate. For example, for a display device having a definition of a QVGA level for 1 inch, it is advantageous to form transistors in a Si substrate.

An organic light-emitting device according to an embodiment may include an organic light-emitting element and a switching element to control the emission of the organic light-emitting element. The switching element, which is connected to the organic light-emitting element, may contain an oxide semiconductor in the active region thereof. The oxide semiconductor may be amorphous or crystalline, or may contain amorphous phases and crystalline phases.

The crystalline phases may be monocrystalline or microcrystalline, or may be oriented in a specific axis such as the C-axis. Crystalline phases in two or more of these states may be mixed.

The organic light-emitting device including such a switching element may be used as an image display device in which organic light-emitting elements act as pixels, or may be used as a lighting device. Alternatively, the organic light-emitting device may be used as an exposure light source of an electrophotographic image forming apparatus, such as a laser beam printer or a copy machine.

FIG. 2 is a schematic view of an image forming apparatus 26 of an embodiment according to the present application. The image forming apparatus includes a photosensitive member 27, an exposure light source 28, a developing portion 30, a charging member 31, a transfer device 32, a conveying roller 33, and a fuser 35.

The exposure light source 28 emits light 29 to form an electrostatic latent image on the surface of the photosensitive member 27. The exposure light source 28 includes the organic light-emitting element according to an embodiment of the present application. The developing portion 30 contains a toner or the like. The charging member 31 charges the photosensitive member 27. The transfer device 32 transfers the developed image to a recording medium 34. The conveying roller 33 conveys the recording medium 34. The recording medium 34 may be a paper sheet. The fuser 35 fixes the image formed on the recording medium.

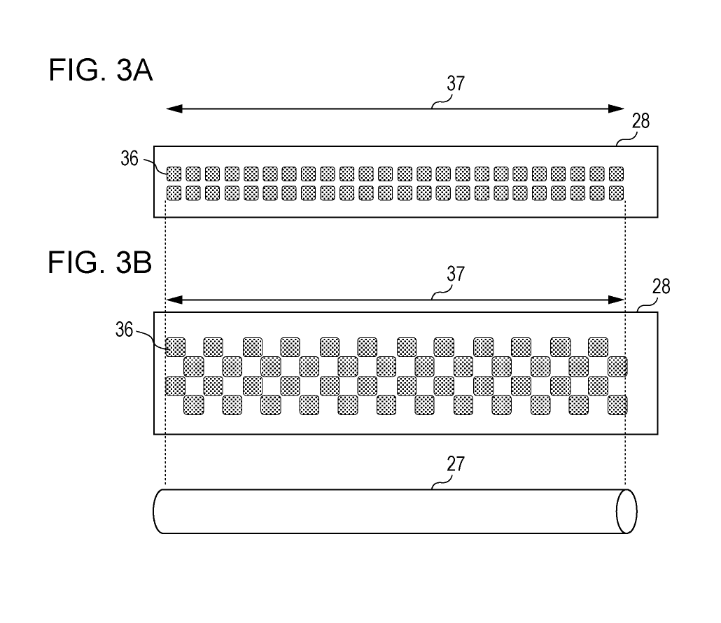

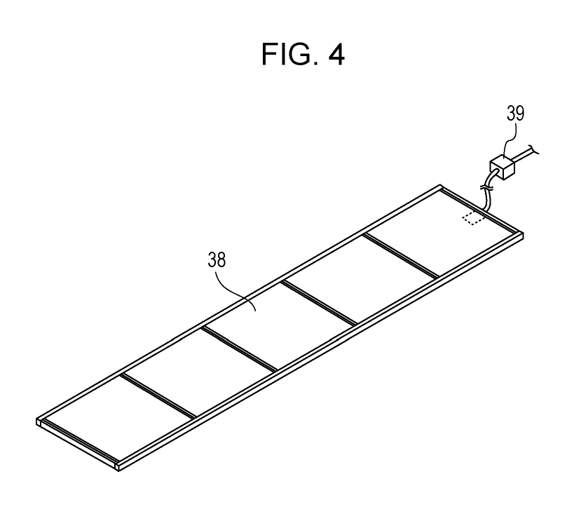

FIGS. 3A and 3B (b) schematically show exposure light sources 28 each having emitting portions 36 arranged on a long substrate. The organic light-emitting elements are arranged so as to extend in the direction indicated by arrows 37. This direction is the same as the direction of the rotation axis of the photosensitive member 27. This direction can be called the longitudinal direction of the photosensitive member.

FIG. 3A shows a form of the photosensitive member in which the emitting portions are arranged along the longitudinal direction of the photosensitive member. FIG. 3B shows a form different from the form shown in FIG. 3A and in which the emitting portions are arranged alternately in first rows and second rows. The emitting portions in the first rows and the emitting portions in the second rows are arranged at different positions in the column direction.

In each first row, the emitting portions are aligned with spaces therebetween. In each second row, the emitting portions are disposed at positions corresponding to the spaces among the emitting portions in the first row. Thus, the emitting portions are arranged with spaces therebetween in the column direction as well.

In other words, the emitting portions shown in FIG. 3B are arranged, for example, in a matrix manner, in a staggered manner, or in a checker.

FIG. 4 is a schematic view of a lighting device according to an embodiment of the present application. The lighting device includes a substrate, organic light-emitting elements 38, and an AC/DC converter 39. In addition, the substrate may be provided with a heat sink plate (not shown) on the surface thereof opposite the organic light-emitting elements.

By operating the display device including the organic light-emitting elements of an embodiment of the present application, high-quality images can stably be displayed over a long time, as described above.

### EXAMPLES

### Example 1

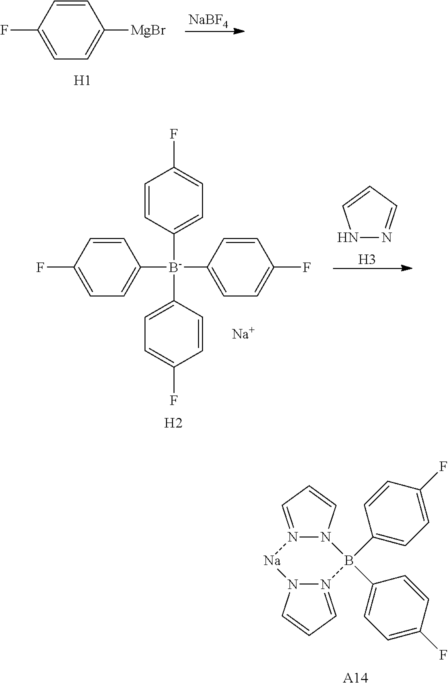

### (1) Synthesis of Compound H2

The following compound and solvent were added to a 200 mL recovery flask:

Compound H1: 100 mL (100 mmol) (1.0 M solution in THF, produced by Aldrich)
NaBF₄: 2195 mg (20 mmol, produced by Wako Pure Chemical Industries)

The mixture was stirred for 24 hours. After the completion of a reaction, THF was removed by evaporation under reduced pressure, and then 100 mL of diethyl ether was added. The resulting solution was gradually added to 150 mL of 2 M sodium carbonate aqueous solution, followed by stirring at room temperature for 30 minutes. Then, the organic phase was separated from the aqueous phase and filtered through celite in a Kiriyama funnel, followed by drying with magnesium sulfate. After the magnesium sulfate was removed by filtration, the diethyl ether was removed by evaporation under reduced pressure, and hexane was added for recrystallization. The resulting crystals were vacuum-dried to yield 6.3 g of Compound H2 (yield: 76%).

### (2) Synthesis of Exemplified Compound A14

The following chemicals were added to a 20 mL recovery flask:

Compound H2: 828 mg (2.0 mmol)
Compound H3: 1360 mg (20.0 mmol, produced by Tokyo Chemical Industry)

These chemicals were mixed, gradually heated, and stirred at 140° C. for 1 hour. The mixture was further heated gradually to 180° C. and subjected to a reaction at this temperature for 1 hour. Then, the reaction liquid was gradually heated to 225° C. and subjected to further reaction for 4 hours. At this time, the reaction was performed while separated and refluxed matter was removed by evaporation.

After the completion of the reaction, the reaction liquid was temporarily cooled, and was then heated to 160° C. at a vacuum of about 10⁻² Pa kept with a vacuum pump for evaporation of unreacted Compound H3 under reduced pressure. The resulting liquid was concentrated into a viscous liquid. The viscous liquid was vacuum-dried at 100° C., and purified by sublimation to yield 279 mg (yield: 39%) of Exemplified Compound A14 in white powder.

The resulting compound was identified and the results are as follows:

### [DART-MS (JEOL AccuTOF+DART)]

Measured value: m/z=357.11; Calculated value: C₁₈H₁₄BF₂N₄Na=358.12

### Example 2

Exemplified compound A2 was synthesized in the same manner as in Example 1, except that Compound H4 (1.0 M solution in THF, produced by Aldrich) shown below was used instead of Compound H1 used in (1) in Example 1.

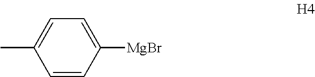

The resulting compound was identified and the results are as follows:

### [DART-MS (JEOL AccuTOF+DART)]

Measured value: m/z=350.22; Calculated value: C₂₀H₂₀BN₄Na=350.17

### Example 3

Exemplified compound A5 was synthesized in the same manner as in Example 1, except that Compound H5 (0.5 M solution in THF, produced by Aldrich) shown below was used instead of Compound H1 used in (1) in Example 1.

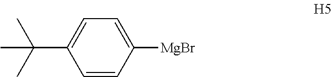

The resulting compound was identified and the results are as follows:

### [DART-MS (JEOL AccuTOF+DART)]

Measured value: m/z=433.67; Calculated value: C₂₆H₃₂BN₄Na=434.26

### Examples 4 and 5, Comparative Examples 1 and 2

An organic light-emitting element was produced by forming an anode, a hole transport layer, an electron blocking layer, a luminescent layer, a hole blocking layer, an electron transport layer and a cathode in that order on a substrate.

First, an ITO layer was formed on a glass substrate and then patterned into an ITO electrode (anode). The thickness of the ITO electrode was 100 nm at that time. The resulting substrate having the ITO electrode thereon was used as an ITO substrate in the subsequent step.

Organic compound layers and an electrode layer, shown in Table 2, were continuously formed on the ITO substrate. At this time, the opposing electrode (metal electrode layer or cathode) was formed with an area of 3 mm².

TABLE 2

| | | Thickness |
|---|---|---|
| | Material | (nm) |
| Hole transport layer | G-1 | 30 |
| Electron blocking layer | G-2 | 10 |
| Luminescent layer | G-3 (Host) | 30 |
| | G-4 (Guest) | |
| | (G-3:G-4 = 98:2 (weight basis) | |
| Hole blocking layer | G-5 | 10 |
| Electron transport layer | G-6 | 15 |
| Electron injection layer | G-7 | 15 |
| | G-8 | |
| | (G-7:G-8 = 50:50 (weight basis) | |
| Metal electrode layer | Al | 100 |

Before forming the metal electrode layer, the element was immersed in water for 10 minutes and then vacuum-dried at 120° C.

Thus, organic light-emitting elements were produced for evaluation, using compounds G1 to G7 shown in Table 3, sodium complex compounds expressed by general formula [1], and comparative compounds 1 and 2, which are described in Table 1.

TABLE 3

| | G1 | G2 | G3 | G4 | G5 | G6 | G7 | G8 | Emission |
|---|---|---|---|---|---|---|---|---|---|
| Example 4 | HT1 | HT7 | EM1 | BD7 | ET2 | ET2 | ET2 | A1 | Good |
| Example 5 | HT1 | HT7 | EM1 | BD7 | ET2 | ET2 | ET2 | A5 | Good |
| Comparative | HT1 | HT7 | EM1 | BD7 | ET2 | ET2 | ET2 | Comparative | Bad |
| Example 1 | | | | | | | | Compound 1 | |
| Comparative | HT1 | HT7 | EM1 | BD7 | ET2 | ET2 | ET2 | Comparative | Bad |
| Example 2 | | | | | | | | Compound 2 | |

Light emission from each organic light-emitting element was examined at a voltage of 4 V. As a result, the elements using the metal complex compounds of general formula [1] emitted light (represented as Good), but the elements using comparative compound (1) or (2) did not emit light (represented as Bad).

This is probably because the comparative compounds deteriorated, or leached away when the element was immersed in water, thus losing the electron injection property thereof.

### Examples 6 to 10

An organic light-emitting element was produced by forming an anode, a hole transport layer, an electron blocking layer, a luminescent layer, a hole blocking layer, an electron transport layer and a cathode in that order on a substrate.

First, an ITO layer was formed on a glass substrate and then patterned into an ITO electrode (anode). The thickness of the ITO electrode was 100 nm at that time. The resulting substrate having the ITO electrode thereon was used as an ITO substrate in the subsequent step.

Organic compound layers and an electrode layer, shown in Table 4, were continuously formed on the ITO substrate. At this time, the opposing electrode (metal electrode layer or cathode) was formed with an area of 3 mm².

TABLE 4

| | | Thickness |
|---|---|---|
| | Material | (nm) |
| Hole transport layer | G-1 | 30 |
| Electron blocking layer | G-2 | 10 |
| Luminescent layer | G-3 (Host) | 30 |
| | G-4 (Guest) | |
| | (G-3:G-4 = 98:2 (weight basis) | |
| Hole blocking layer | G-5 | 10 |
| Electron transport layer | G-6 | 15 |
| Electron injection layer | G-7 | 15 |
| | G-8 | |
| | (G-7:G-8 = 50:50 (weight basis) | |
| Metal electrode layer | Al | 100 |

Thus, organic light-emitting elements were produced for evaluation, using compounds G1 to G8 shown in Table 5 including sodium complex compounds expressed by general formula [1].

TABLE 5

| | | | | | | | | | Emission | |
|---|---|---|---|---|---|---|---|---|---|---|
| | | | | | | | | | efficiency | Voltage |
| | G1 | G2 | G3 | G4 | G5 | G6 | G7 | G8 | (cd/A) | (V) |
| Example 6 | HT6 | HT7 | EM4 | BD6 | ET4 | ET3 | ET3 | A1 | 5 | 5 |
| Example 7 | HT6 | HT8 | EM13 | RD1 | EM17 | ET2 | ET2 | A4 | 4 | 5 |
| Example 8 | HT2 | HT10 | EM7 | GD7 | ET4 | ET3 | ET3 | A5 | 15 | 5 |
| Example 9 | HT2 | HT7 | EM1 | BD4 | ET5 | ET5 | ET3 | A14 | 5 | 6 |
| Example 10 | HT5 | HT8 | EM12 | RD1 | ET9 | ET3 | ET3 | C4 | 4 | 5 |

For the element of Example 7, the durability with time was measured. As a result, it took a long time of 1000 hours or more to reduce a luminance of 1000 cd/m² by 5%.

### Examples 11 to 13

An organic light-emitting element was produced by forming an anode, a hole transport layer, an electron blocking layer, a luminescent layer, a hole blocking layer, an electron transport layer and a cathode in that order on a substrate.

First, an ITO layer was formed on a glass substrate and then patterned into an ITO electrode (anode). The thickness of the ITO electrode was 100 nm at that time. The resulting substrate having the ITO electrode thereon was used as an ITO substrate in the subsequent step.

Organic compound layers and an electrode layer, shown in Table 6, were continuously formed on the ITO substrate. At this time, the opposing electrode (metal electrode layer or cathode) was formed with an area of 3 mm².

TABLE 6

| | | Thickness |
|---|---|---|
| | Material | (nm) |
| Hole transport layer | G-1 | 30 |
| Electron blocking layer | G-2 | 10 |
| Luminescent layer | G-3 (Host) | 30 |
| | G-4 (Guest) | |
| | (G-3:G-4 = 98:2 (weight basis) | |
| Hole blocking layer | G-5 | 10 |
| Electron transport layer | G-6 | 25 |
| Electron injection layer | G-8 | 5 |
| Metal electrode layer | Al | 100 |

Organic light-emitting elements were produced for evaluation, using compounds G1 to G8 shown in Table 7 including sodium complex compounds expressed by general formula [1].

TABLE 7

| | | | | | | | | Emis- | |
|---|---|---|---|---|---|---|---|---|---|
| | | | | | | | | sion | |
| | | | | | | | | effi- | Volt- |
| | | | | | | | | ciency | age |
| | G1 | G2 | G3 | G4 | G5 | G6 | G8 | (cd/A) | (V) |
| Example | HT6 | HT9 | EM2 | BD1 | ET2 | ET3 | A1 | 5 | 5 |
| 11 | | | | | | | | | |
| Example | HT2 | HT9 | EM1 | GD1 | ET4 | ET2 | A4 | 18 | 5 |
| 12 | | | | | | | | | |
| Example | HT2 | HT8 | EM10 | RD4 | ET4 | ET3 | A16 | 12 | 4 |
| 13 | | | | | | | | | |

As described above with reference to the Examples, by using a sodium complex compound expressed by general formula in the electron injection layer in contact with the metal electrode in an organic light-emitting element, the element can be stable to water. Thus, the light-emitting element can be stable and have long life.

### Example 14

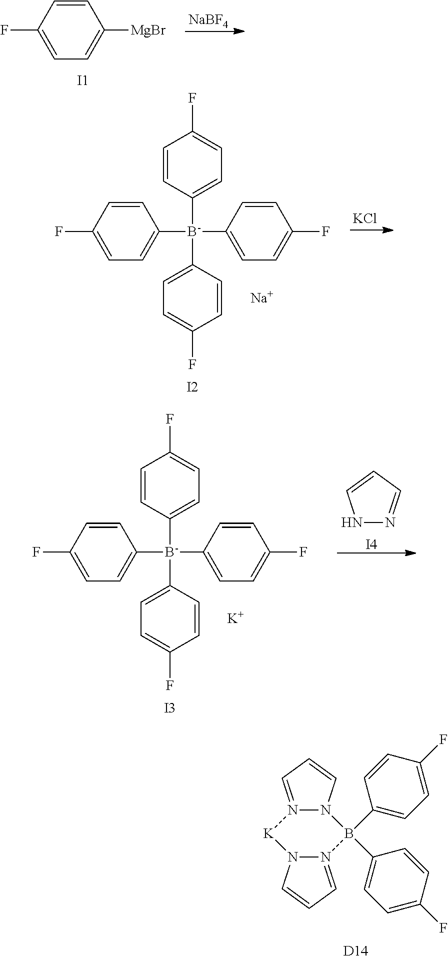

### (1) Synthesis of Compound I2

The following compound and solvent were added to a 200 mL recovery flask:

Compound I1: 100 mL (100 mmol) (1.0 M solution in THF, produced by Aldrich)
NaBF₄: 2195 mg (20 mmol, produced by Wako Pure Chemical Industries)

The mixture was stirred for 24 hours. After the completion of a reaction, THF was removed by evaporation under reduced pressure, and then 100 mL of diethyl ether was added. The resulting solution was gradually added to 150 mL of 2 M potassium carbonate aqueous solution, followed by stirring at room temperature for 30 minutes. Then, the organic phase was separated from the aqueous phase and filtered through celite in a Kiriyama funnel, followed by drying with magnesium sulfate. After the magnesium sulfate was removed by filtration, the diethyl ether was removed by evaporation under reduced pressure, and hexane was added for recrystallization. The resulting crystals were vacuum-dried to yield 6.3 g of Compound I2 (yield: 76%).

### (2) Synthesis of Compound I3

To 6.3 g (15 mmol) of Compound I2, 100 mL of diethyl ether was added. After adding 3.0 g (40 mmol) of KCl, 100 mL of distilled water was added, followed by stirring for 1 hour. Then, the organic phase was separated from the aqueous phase and rinsed three times with water, followed by drying with magnesium sulfate. After the magnesium sulfate was removed by filtration, the diethyl ether was removed by evaporation under reduced pressure. The resulting powder was dried at 160° C. for 6 hours under reduced pressure to yield 5.2 g of Compound I3 (yield: 80%).

### (3) Synthesis of Exemplified Compound D14

The following chemicals were added to a 20 mL recovery flask:

Compound I3: 860 mg (2.0 mmol)
Compound I4: 1360 mg (20.0 mmol, produced by Tokyo Chemical Industry)

These chemicals were mixed, gradually heated, and stirred at 140° C. for 1 hour. The mixture was further heated gradually to 180° C. and subjected to a reaction at this temperature for 1 hour. Then, the reaction liquid was gradually heated to 225° C. and subjected to further reaction for 4 hours. At this time, the reaction was performed while separated and refluxed matter was removed by evaporation.

After the completion of the reaction, the reaction liquid was temporarily cooled, and was then heated to 160° C. at a vacuum of about 10⁻² Pa kept with a vacuum pump for evaporation of unreacted Compound I3 under reduced pressure. The resulting liquid was concentrated into a viscous liquid. The viscous liquid was vacuum-dried at 100° C., and purified by sublimation to yield 149 mg (yield: 20%) of Exemplified Compound D14 in white powder.

The resulting compound was identified and the results are as follows:

### [DART-MS (JEOL AccuTOF+DART)]

Measured value: m/z=375.11; Calculated value: C₁₈H₁₄BF₂N₄K=374.09; ¹H NMR (CDCl₃, 500 MHz) σ (ppm): 7.49 (s, 2H), 7.07-7.11 (m, 4H), 6.90 (s, 2H), 6.81-0.87 (m, 4H), 6.00 (d, 2H)

### Example 15

Exemplified compound D5 was synthesized in the same manner as in Example 14, except that Compound I5 (0.5 M solution in THF, produced by Aldrich) shown below was used instead of Compound I1 used in (1) in Example 14.

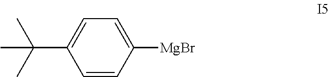

The resulting compound was identified and the results are as follows:

### [DART-MS (JEOL AccuTOF+DART)]

Measured value: m/z=433.67; Calculated value: C₂₆H₃₂BN₄K=434.26

### Example 16

Exemplified compound D16 was synthesized in the same manner as in Example 14, except that Compound I6 (1.0 M solution in THF, produced by Aldrich) shown below was used instead of Compound I1 used in (1) in Example 14.

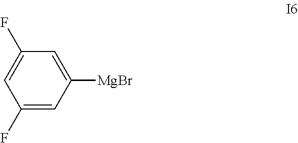

The resulting compound was identified and the results are as follows:

### [DART-MS (JEOL AccuTOF+DART)]

Measured value: m/z=409.88; Calculated value: C₁₈H₁₂BF₂N₄K=410.07

### Examples 17 and 18, Comparative Examples 3 and 4

An organic light-emitting element was produced by forming an anode, a hole transport layer, an electron blocking layer, a luminescent layer, a hole blocking layer, an electron transport layer and a cathode in that order on a substrate.

First, an ITO layer was formed on a glass substrate and then patterned into an ITO electrode (anode). The thickness of the ITO electrode was 100 nm at that time. The resulting substrate having the ITO electrode thereon was used as an ITO substrate in the subsequent step.

Organic compound layers and an electrode layer, shown in Table 8, were continuously formed on the ITO substrate. At this time, the opposing electrode (metal electrode layer or cathode) was formed with an area of 3 mm².

TABLE 8

| | | Thickness |
|---|---|---|
| | Material | (nm) |
| Hole transport layer | G-1 | 30 |
| Electron blocking layer | G-2 | 10 |
| Luminescent layer | G-3 (Host) | 30 |
| | G-4 (Guest) | |
| | (G-3:G-4 = 98:2 (weight basis) | |
| Hole blocking layer | G-5 | 10 |
| Electron transport layer | G-6 | 15 |
| Electron injection layer | G-7 | 15 |
| | G-8 | |
| | (G-7:G-8 = 50:50 (weight basis) | |
| Metal electrode layer | Al | 100 |

Before forming the metal electrode layer, the element was immersed in water for 10 minutes and then vacuum-dried at 120° C.

Thus, organic light-emitting elements were produced for evaluation, using compounds G1 to G7 shown in Table 9, potassium complex compounds expressed by general formula [1], and comparative compounds 1 and 2.

TABLE 9

| | G1 | G2 | G3 | G4 | G5 | G6 | G7 | G8 | Emission |
|---|---|---|---|---|---|---|---|---|---|
| Example 17 | HT1 | HT7 | EM1 | BD7 | ET2 | ET2 | ET2 | D1 | Good |
| Example 18 | HT1 | HT7 | EM1 | BD7 | ET2 | ET2 | ET2 | D14 | Good |
| Comparative | HT1 | HT7 | EM1 | BD7 | ET2 | ET2 | ET2 | Comparative | Bad |
| Example 3 | | | | | | | | Compound 1 | |
| Comparative | HT1 | HT7 | EM1 | BD7 | ET2 | ET2 | ET2 | Comparative | Bad |
| Example 4 | | | | | | | | Compound 2 | |

Light emission from each element was examined at a voltage of 4 V. As a result, the elements using the potassium complex compounds according to the application emitted light (represented as good), but the elements using comparative compound 1 or 2 did not emit light (represented as bad).

This is probably because the comparative compounds deteriorated, or leached away when the element was immersed in water, thus losing the electron injection property thereof.

### Examples 19 to 23

An organic light-emitting element was produced by forming an anode, a hole transport layer, an electron blocking layer, a luminescent layer, a hole blocking layer, an electron transport layer and a cathode in that order on a substrate.

First, an ITO layer was formed on a glass substrate and then patterned into an ITO electrode (anode). The thickness of the ITO electrode was 100 nm at that time. The resulting substrate having the ITO electrode thereon was used as an ITO substrate in the subsequent step.

Organic compound layers and an electrode layer, shown in Table 10, were continuously formed on the ITO substrate. At this time, the opposing electrode (metal electrode layer or cathode) was formed with an area of 3 mm².

TABLE 10

| | | Thickness |
|---|---|---|
| | Material | (nm) |
| Hole transport layer | G-1 | 30 |
| Electron blocking layer | G-2 | 10 |
| Luminescent layer | G-3 (Host) | 30 |
| | G-4 (Guest) | |
| | (G-3:G-4 = 98:2 (weight basis) | |
| Hole blocking layer | G-5 | 10 |
| Electron transport layer | G-6 | 15 |
| Electron injection layer | G-7 | 15 |
| | G-8 | |
| | (G-7:G-8 = 50:50 (weight basis) | |
| Metal electrode layer | Al | 100 |

Organic light-emitting elements were produced for evaluation, using compounds G1 to G8 shown in Table 11 including potassium complex compounds expressed by general formula [1].

TABLE 11

| | | | | | | | | | Emission | |
|---|---|---|---|---|---|---|---|---|---|---|
| | | | | | | | | | efficiency | Voltage |
| | G1 | G2 | G3 | G4 | G5 | G6 | G7 | G8 | (cd/A) | (V) |
| Example 19 | HT6 | HT7 | EM12 | RD2 | ET6 | ET3 | ET3 | D1 | 4 | 5 |
| Example 20 | HT2 | HT7 | EM9 | RD4 | EM5 | ET3 | ET2 | D5 | 10 | 6 |
| Example 21 | HT6 | HT7 | EM4 | BD7 | ET10 | ET5 | ET3 | D14 | 7 | 4 |
| Example 22 | HT6 | HT7 | EM4 | BD6 | ET4 | ET5 | ET3 | D16 | 5 | 4 |
| Example 23 | HT5 | HT8 | EM1 | GD1 | ET4 | ET3 | ET3 | F4 | 16 | 5 |

For the element of Example 19, the durability with time was measured. As a result, it took a long time of 1000 hours or more to reduce a luminance of 1000 cd/m² by 5%.

### Examples 24 to 26

An organic light-emitting element was produced by forming an anode, a hole transport layer, an electron blocking layer, a luminescent layer, a hole blocking layer, an electron transport layer and a cathode in that order on a substrate.

First, an ITO layer was formed on a glass substrate and then patterned into an ITO electrode (anode). The thickness of the ITO electrode was 100 nm at that time. The resulting substrate having the ITO electrode thereon was used as an ITO substrate in the subsequent step.

Organic compound layers and an electrode layer, shown in Table 12, were continuously formed on the ITO substrate. At this time, the opposing electrode (metal electrode layer or cathode) was formed with an area of 3 mm².

TABLE 12

| | | Thickness |
|---|---|---|
| | Material | (nm) |
| Hole transport layer | G-1 | 30 |
| Electron blocking layer | G-2 | 10 |
| Luminescent layer | G-3 (Host) | 30 |
| | G-4 (Guest) | |
| | (G-3:G-4 = 98:2 (weight basis) | |
| Hole blocking layer | G-5 | 10 |
| Electron transport layer | G-6 | 25 |
| Electron injection layer | G-8 | 5 |
| Metal electrode layer | Al | 100 |

Organic light-emitting elements were produced for evaluation, using compounds G1 to G8 shown in Table 13 including potassium complex expressed by general formula [1].

TABLE 13

| | | | | | | | | Emis- | |
|---|---|---|---|---|---|---|---|---|---|
| | | | | | | | | sion | |
| | | | | | | | | effi- | Volt- |
| | | | | | | | | ciency | age |
| | G1 | G2 | G3 | G4 | G5 | G6 | G8 | (cd/A) | (V) |
| Example | HT2 | HT9 | EM3 | BD4 | ET2 | ET3 | D1 | 5 | 4 |
| 24 | | | | | | | | | |
| Example | HT2 | HT9 | EM8 | GD6 | ET4 | ET2 | D8 | 30 | 5 |
| 25 | | | | | | | | | |
| Example | HT2 | HT8 | EM10 | RD7 | ET4 | ET3 | D16 | 12 | 6 |
| 26 | | | | | | | | | |

As described above with reference to the Examples, by using a potassium complex compound of an embodiment according to the application in the organic compound layer in contact with the cathode of an organic light-emitting element, the element can be stable to water. Thus, the light-emitting element can be stable and have long life.

As described above, the organic light-emitting element of an embodiment according to the application includes an organic compound layer containing a sodium or a potassium complex compound expressed by general formula [1] adjacent to the cathode. The use of such a metal complex compound achieves an organic light-emitting element stable to water or moisture. Thus, the organic light-emitting element can exhibit high emission efficiency and long life.

The present application provides a metal complex compound having high electron injection property and a low water solubility.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-089535, filed Apr. 23, 2014 and No. 2014-093085, filed Apr. 28, 2014, which are hereby incorporated by reference herein in their entirety.

What is claimed is:

1. A metal complex compound expressed by the following general formula [1]: 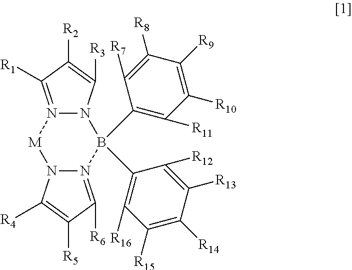
wherein M represents sodium or potassium, R₁ to R₁₆ each represent hydrogen or a substituent selected from the group consisting of halogen atoms, a cyano group, alkyl groups that may be substituted with an halogen atom, alkoxy groups that may be substituted with an halogen atom, and aromatic hydrocarbon groups that may be substituted with at least one species selected from the group consisting of halogen atoms, substituted or unsubstituted alkyl groups, substituted or unsubstituted alkoxy groups, substituted amino groups, a cyano group, and substituted or unsubstituted aromatic hydrocarbon groups, and wherein at least one of the R₁ to R₁₆ is the substituent.

2. The metal complex compound according to claim 1, wherein the R₁ to R₆ are each a hydrogen atom.

3. The metal complex compound according to claim 2, wherein the R₇, R₁₁, R₁₂, and R₁₆ are each a hydrogen atom.

4. The metal complex compound according to claim 3, wherein the R₈ to R₁₀ and the R₁₃ to R₁₅ are each a species selected from the group consisting of the halogen atoms, the alkyl groups, and the aromatic hydrocarbon groups.

5. An organic light emitting element comprising:
an anode;
a cathode;
a luminescent layer disposed between the anode and the cathode; and
an organic compound layer in contact with the cathode between the cathode and the luminescent layer, the organic compound layer containing a metal complex compound expressed by the following general formula [1]: 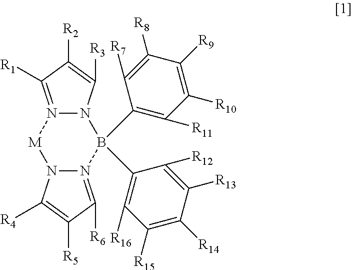
wherein M represents sodium or potassium, and R₁ to R₁₆ each represent a hydrogen atom or a substituent selected from the group consisting of halogen atoms, a cyano group, alkyl groups that may be substituted with a halogen atom, alkoxy groups that may be substituted with a halogen atom, and aromatic hydrocarbon groups that may be substituted with at least one species selected from the group consisting of halogen atoms, substituted or unsubstituted alkyl groups, substituted or unsubstituted alkoxy groups, substituted amino groups, substituted or unsubstituted aromatic hydrocarbon groups.

6. The organic light emitting element according to claim 5, wherein the organic compound layer further contains a second compound different from the metal complex compound with a content of more than 0% by weight and 80% by weight or less relative to the total weight of the organic compound layer.

7. The organic light emitting element according to claim 5, wherein the R₁ to R₆ of the metal complex compound are each a hydrogen atom.

8. The organic light emitting element according to claim 5, wherein the R₇, R₁₁, R₁₂ and R₁₆ of the metal complex compound are each a hydrogen atom.

9. The organic light emitting element according to claim 5, wherein the R₈ to R₁₀ and the R₁₃ to R₁₅ of the metal complex compound are each a species selected from the group consisting of the halogen atoms, the alkyl groups and the aromatic hydrocarbon groups.

10. A display device comprising:
a plurality of pixels, at least one of which includes the organic light emitting element as set forth in claim 5 and an active element connected to the organic light emitting element.

11. The display device according to claim 10, wherein the active element is a transistor having an active region containing an oxide semiconductor.

12. An image information processing unit comprising:
an information processing portion configured to process image information; and
a display portion to which the image information is input, the display portion being the display device as set forth in claim 10.

13. A lightning device comprising:
the organic light-emitting element as set forth in claim 5; and
an AC/DC converter connected to the organic light-emitting element.

14. A lightning device comprising:
the organic light-emitting element as set forth in claim 5; and
a heat radiation portion configured to dissipate heat from the lightning device.

15. An image forming apparatus comprising:
a photosensitive member;
a charging member configured to charge the photosensitive member;
an exposure portion including the organic light-emitting element as set forth in claim 5, the exposure portion being configured to expose the photosensitive member to form an electrostatic latent image on the photosensitive member; and
a developing portion that develops the electrostatic latent image.

16. An exposure unit adapted to expose a photosensitive member having a longitudinal axis, the exposure unit comprising:
a plurality of organic light-emitting elements as set forth in claim 5, arranged in a line along the longitudinal axis of the photosensitive member.
